(19) United States
(12) Patent Application Publication
(10) Pub. No.: US 2025/0113665 A1
(43) Pub. Date: Apr. 3, 2025

(54) A MICRO LED PANEL WITH RE-GROWTH LAYER AND MANUFACTURING METHOD THEREOF

(71) Applicant: Jade Bird Display (Shanghai) Limited, Pudong New Area, Shanghai (CN)

(72) Inventors: Yuankun ZHU, Shanghai (CN); Anle FANG, Shanghai (CN); Deshuai LIU, Shanghai (CN)

(73) Assignee: Jade Bird Display (Shanghai) Limited, Pudong New Area, Shanghai (CN)

(21) Appl. No.: 18/832,119

(22) PCT Filed: Jan. 31, 2022
(86) PCT No.: PCT/CN2022/075276

§ 371 Date: Jul. 23, 2024

(51) Int. Cl. H10H 20/821; H10H 20/812; H10H 29/24; H10H 29/37

(52) U.S. Cl. CPC H10H 20/821; H10H 20/812; H10H 29/24; H10H 29/37

(57) ABSTRACT

A micro LED panel having a micro LED array and the system and method to manufacture the micro LED panel are provided in the present disclosure. The micro LED array includes at least one micro LED structure. The micro LED structure at least includes: a mesa structure and a re-growth layer. In some embodiments, the mesa structure comprises a light-emitting layer. In some embodiments, the re-growth layer is grown at least on the sidewall of the light-emitting layer. The re-growth layer is not parallel to the extending direction of the light-emitting layer.

### TECHNICAL FIELD

The present disclosure generally relates to light emitting diode (LED) technology and, more particularly, to a micro LED panel and a method of manufacturing the micro LED structure.

### BACKGROUND

Display technologies are becoming increasingly important in today's commercial electronic devices. These display panels are widely used in stationary large screens such as liquid crystal display televisions (LCD TVs) and organic light emitting diode televisions (OLED TVs) as well as portable electronic devices such as laptop personal computers, smartphones, tablets and wearable electronic devices.

Inorganic micro light emitting diodes are of increasing importance because of their use in various applications including self-emissive micro-displays, visible light communications and opto-genetics. The micro LEDs show higher output performance than conventional LEDs due to better strain relaxation, improved light extraction efficiency, and uniform current spreading. The micro LEDs also exhibit improved thermal effects, and operate at a higher current density, fast response rate, larger work temperature range, higher resolution, color gamut, and contrast and lower power consumption as compared with conventional LEDs.

To achieve higher pixel density, the size of the micro LEDs is reduced to less than 200 nm. However, the efficiency and the carrier lifetime of the micro LED array based device degrade drastically with the reduced micro LED size to a large extent, by surface recombination and poor p-type conduction induced by top-down etching. The performance of micro LEDs also suffers severely from quantum-confined stark effect, particularly due to the strain-induced polarization field, which leads to unstable operation, and significant variations in emission wavelengths with increasing current. Additionally, with the decrease of the micro LED diameter, a large number of surface states and defects are formed at the surface of the micro LED structure by Inductively Coupled Plasma (ICP) etching, which increases the non-radiation recombination at the surface of the micro LED structures.

Additionally, the emission of the conventional micro LED structure is mainly distributed at any direction which exhibits poor directional emission and reduces the light intensity along the vertical direction. To realize the directional emission of the micro LED structure, extra reflective structures are configured around the mesa of the micro LED structure and at the bottom of the mesa, so as to reflect the emission light to a same direction, which causes a complex manufacturing process and increases the cost of the micro LED.

Furthermore, in the micro LED array based device, one micro LED is conventionally used as one pixel such as in monolithic micro LED array panel. However, the micro LED structure with smaller diameter shows lower external quantum efficiency (EQE), which reduces the light efficiency of each pixel.

The above content is only used to assist in understanding the technical solutions of the present application, and does not constitute an admission that the above is prior art.

### SUMMARY

There is a need for improved display designs that improve upon, and help to address the shortcomings of conventional display systems, such as those described above. In particular, there is a need for display panels with improved efficiency with better images.

In order to overcome the drawback mentioned above, the present invention provides a micro LED panel, to improve the light emitting efficiency, to avoid crosstalk, to minimize the surface carrier loss, and to optimize the quantum well sidewall area.

To achieve the above objectives, in one aspect of some exemplary embodiments, the present disclosure provides a micro LED panel having a micro LED array, comprising: at least one micro LED structure, wherein the micro LED structure at least comprises: a mesa structure, wherein the mesa structure from bottom to top comprises: a first-type epitaxial layer, a light-emitting layer and a second-type epitaxial layer; and, a re-growth layer, grown at least on a sidewall of the light-emitting layer.

In some exemplary embodiments or any combination of preceding exemplary embodiments of the micro LED panel, the re-growth layer is grown on the whole sidewall of the light-emitting layer and part of the second-type epitaxial layer.

In some exemplary embodiments or any combination of preceding exemplary embodiments of the micro LED panel, the re-growth layer is not parallel to an extending direction of the light-emitting layer.

In some exemplary embodiments or any combination of preceding exemplary embodiments of the micro LED panel, an inclined angle of the re-growth layer relative to the extending direction of the light-emitting layer is 30 degrees to 90 degrees.

In some exemplary embodiments or any combination of preceding exemplary embodiments of the micro LED panel, the diameter of the mesa structure is not more than 3 μm.

In some exemplary embodiments or any combination of preceding exemplary embodiments of the micro LED panel, the light-emitting layer comprises a top surface, an edge surface, and a bottom surface; and the re-growth layer is only grown on the edge surface of the light-emitting layer and not grown on the top surface and the bottom surface of the light-emitting layer.

In some exemplary embodiments or any combination of preceding exemplary embodiments of the micro LED panel, the light-emitting layer comprises a plurality of pairs of quantum wells and the re-growth layer is not parallel to surface of each of the plurality of pairs of quantum wells.

In some exemplary embodiments or any combination of preceding exemplary embodiments of the micro LED panel, the light-emitting layer has a straight-line shape without any bending.

In some exemplary embodiments or any combination of preceding exemplary embodiments of the micro LED panel, material of the re-growth layer with intrinsic doped ions is the same as the material of the first-type epitaxial layer and/or material of the second-type epitaxial layer but without the intentional doping ions.

In some exemplary embodiments or any combination of preceding exemplary embodiments of the micro LED panel, material of the re-growth layer is at least one selected from a group consisting of GaP, AlP, GaAs, InP, AlInP, GaInP, AlN, GaN, and InN.

In some exemplary embodiments or any combination of preceding exemplary embodiments of the micro LED panel, the material of the re-growth layer is monocrystal, the material of the first epitaxial layer is monocrystal, and the material of the second epitaxial layer is monocrystal.

In some exemplary embodiments or any combination of preceding exemplary embodiments of the micro LED panel, a band gap of the re-growth layer is greater than a band gap of the light-emitting layer.

In some exemplary embodiments or any combination of preceding exemplary embodiments of the micro LED panel, the thickness of the re-growth layer is less than the thickness of the light-emitting layer.

In some exemplary embodiments or any combination of preceding exemplary embodiments of the micro LED panel, the thickness of the re-growth layer is not more than 100 nm.

In some exemplary embodiments or any combination of preceding exemplary embodiments of the micro LED panel, the resistance of the re-growth layer is higher than the resistance of the light-emitting layer.

In some exemplary embodiments or any combination of preceding exemplary embodiments of the micro LED panel, the re-growth layer is not electrically conductive.

In some exemplary embodiments or any combination of preceding exemplary embodiments of the micro LED panel, a dielectric layer is further formed between adjacent mesa structures and on the surface of the re-growth layer.

In some exemplary embodiments or any combination of preceding exemplary embodiments of the micro LED panel, a bottom-connected structure is formed at bottom of the mesa structure and electrically connected to the first-type epitaxial layer, and a top conductive layer is formed on the second-type epitaxial layer and electrically connected to the second-type epitaxial layer.

In some exemplary embodiments or any combination of preceding exemplary embodiments of the micro LED panel, the material of the dielectric layer is one or more of SiO₂, SiNx, Al₂O₃, AlN, HfO₂, TiO₂, and/or ZrO₂, etc.

In some exemplary embodiments or any combination of preceding exemplary embodiments of the micro LED panel, the material of the first-type epitaxial layer is one or more of p-type GaAs, InGaAs, GaP, GaN, InGaN, AlGaN, AlInP, GaInP, and/or AlGaInP; and the material of the second-type epitaxial layer is one or more of n-type GaAs, InGaAs, GaP, GaN, InGaN, AlGaN, AlInP, GaInP, and/or AlGaInP.

In another aspect of some exemplary embodiments, the present disclosure provides a method of manufacturing the micro LED panel, comprising:
step 1, supplying a semiconductor substrate with an epitaxial structure, wherein the epitaxial structure comprises a first-type epitaxial layer, a light-emitting layer, and a second-type epitaxial layer from top down;
step 2, forming a mesa structure by patterning the epitaxial structure;
step 3, forming a mask pattern on the semiconductor substrate to expose the sidewall of the light-emitting layer;
step 4, forming a re-growth layer on the sidewall of the light-emitting layer by an epitaxial material re-growth process;
step 5, removing the mask pattern;
step 6, depositing a dielectric layer on the re-growth layer and forming an opening in the dielectric layer on the surface of the first-type epitaxial layer, and then, forming a bottom contact in the opening;
step 7, forming a bottom-connected structure in the opening;
step 8, bonding the bottom-connected structure with an IC backplane by turning the semiconductor substrate upside down, and then, removing the semiconductor substrate; and
step 9, forming a top contact and a top conductive layer on the second-type epitaxial layer.

In some exemplary embodiments or any combination of preceding exemplary embodiments of the method of manufacturing the micro LED panel, in step 3, the mask pattern comprises a first mask pattern covering the first-type epitaxial layer and a second mask pattern covering the semiconductor substrate and sidewall of the second-type epitaxial layer.

In some exemplary embodiments or any combination of preceding exemplary embodiments of the method of manufacturing the micro LED panel, in step 4, the epitaxial material re-growth process comprises: the re-growth layer is grown on the sidewall of the light-emitting layer and an epitaxial material is deposited on surface of the first mask pattern and the second mask pattern.

In some exemplary embodiments or any combination of preceding exemplary embodiments of the method of manufacturing the micro LED panel, step 8 further comprises: removing the epitaxial material on the second mask pattern by etching the epitaxial material.

In some exemplary embodiments or any combination of preceding exemplary embodiments of the method of manufacturing the micro LED panel, in step 4, in the re-growth process, the temperature is 400° C. to 1000° C., the re-growth time is 5 seconds to 1000 seconds.

In some exemplary embodiments or any combination of preceding exemplary embodiments of the method of manufacturing the micro LED panel, the top conductive layer is continuously formed on a whole micro LED panel.

In another aspect of some exemplary embodiments, the present disclosure provides a micro LED panel, comprising: a micro LED structure array comprising at least two micro LED structures, wherein each micro LED structure comprises: a mesa structure, wherein the mesa structure from bottom to top comprises: a first-type epitaxial layer and a light-emitting layer; a second-type epitaxial layer, continuously formed on top of the light-emitting layer and top of the re-growth layer; and, continuously formed on the whole micro LED panel; and, a re-growth layer, grown on the whole sidewall of the light-emitting layer and fully filled between adjacent light-emitting layers of adjacent micro LED structures.

In some exemplary embodiments or any combination of preceding exemplary embodiments of the micro LED panel, the bottom width of the re-growth layer is the same as the space width between the adjacent light-emitting layers.

In some exemplary embodiments or any combination of preceding exemplary embodiments, the micro LED panel further includes a dielectric layer formed at the bottom of the re-growth layer between adjacent mesa structures of the adjacent micro LED structures.

In some exemplary embodiments or any combination of preceding exemplary embodiments of the micro LED panel, the material of the dielectric layer is one or more of SiO₂, SiNx, Al₂O₃, AlN, HfO₂, TiO₂, and/or ZrO₂, etc.

In some exemplary embodiments or any combination of preceding exemplary embodiments, the micro LED panel further includes a bottom-connected structure formed in the dielectric layer below and electrically connected to the first-type epitaxial layer.

In some exemplary embodiments or any combination of preceding exemplary embodiments of the micro LED panel, the diameter of the mesa structure is not more than 3 μm.

In some exemplary embodiments or any combination of preceding exemplary embodiments of the micro LED panel, the light-emitting layer comprises a top surface, an edge surface, and a bottom surface; and the re-growth layer is grown on the edge surface of the light-emitting layer and not grown on the top surface and the bottom surface of the light-emitting layer.

In some exemplary embodiments or any combination of preceding exemplary embodiments of the micro LED panel, the light-emitting layer comprises a plurality of pairs of quantum wells.

In some exemplary embodiments or any combination of preceding exemplary embodiments of the micro LED panel, the light-emitting layer has a straight-line shape without any bending.

In some exemplary embodiments or any combination of preceding exemplary embodiments of the micro LED panel, material of the re-growth layer with intrinsic doped ions is the same as the material of the first-type epitaxial layer and/or the material of the second-type epitaxial layer but without the intentional doping ions.

In some exemplary embodiments or any combination of preceding exemplary embodiments of the micro LED panel, the material of the re-growth layer is selected from at least one of GaP, AlP, GaAs, InP, AlInP, GaInP, AlN, GaN, and/or InN.

In some exemplary embodiments or any combination of preceding exemplary embodiments of the micro LED panel, the material of the re-growth layer is monocrystal, the material of the first epitaxial layer is monocrystal, and the material of the second epitaxial layer is monocrystal.

In some exemplary embodiments or any combination of preceding exemplary embodiments of the micro LED panel, a band gap of the re-growth layer is greater than a band gap of the light-emitting layer.

In some exemplary embodiments or any combination of preceding exemplary embodiments of the micro LED panel, the thickness of the re-growth layer is less than the thickness of the light-emitting layer.

In some exemplary embodiments or any combination of preceding exemplary embodiments of the micro LED panel, the thickness of the re-growth layer is not more than 100 nm.

In some exemplary embodiments or any combination of preceding exemplary embodiments of the micro LED panel, the resistance of the re-growth layer is higher than the resistance of the light-emitting layer.

In some exemplary embodiments or any combination of preceding exemplary embodiments of the micro LED panel, the re-growth layer is not electrically conductive.

In some exemplary embodiments or any combination of preceding exemplary embodiments of the micro LED panel, the material of the first-type epitaxial layer is one or more of p-type GaAs, InGaAs, GaP, GaN, InGaN, AlGaN, AlInP, GaInP, and/or AlGaInP, etc.; and material of the second-type epitaxial layer is one or more of n-type GaAs, InGaAs, GaP, GaN, InGaN, AlGaN, AlInP, GaInP, and/or AlGaInP, etc.

In another aspect of some exemplary embodiments, the present disclosure provides a method of manufacturing the micro LED panel, comprising:
step 1, supplying a semiconductor substrate with an epitaxial structure, wherein the epitaxial structure comprises a first-type epitaxial layer, a light-emitting layer, and a second-type epitaxial layer from top down;
step 2, forming a mesa structure by patterning the first-type epitaxial layer and the light-emitting layer;
step 3, forming a re-growth layer on the whole sidewall of the light-emitting layer by an epitaxial material re-growth process;
step 4, forming a dielectric layer on the re-growth layer and forming an opening in the dielectric layer on the first-type epitaxial layer, and then, forming a bottom contact in the opening on the surface of the first-type epitaxial layer;
step 5, forming a bottom-connected structure in the opening;
step 6, bonding the bottom-connected structure with an IC backplane by turning the semiconductor substrate upside down, and then, removing the semiconductor substrate; and
step 7, forming a top contact and a top conductive layer on the second epitaxial layer.

In some exemplary embodiments or any combination of preceding exemplary embodiments of the method of manufacturing the micro LED panel, in step 3, in the re-growth process, the temperature is 400° C. to 1000° C., the re-growth time is 5 seconds to 1000 seconds.

In another aspect of some exemplary embodiments, the present disclosure provides a micro LED panel, comprising: a micro LED structure array comprising at least one micro LED structure, wherein the micro LED structure comprises: a mesa structure, wherein the mesa structure from bottom to top comprises: a first-type epitaxial layer, a light-emitting layer, and a second-type epitaxial layer; and a re-growth layer, grown at least on the sidewall of the light-emitting layer; a dielectric layer, formed between adjacent mesa structures of adjacent micro LED structures, wherein the top end of the re-growth layer is further extruded into the dielectric layer.

In some exemplary embodiments or any combination of preceding exemplary embodiments of the micro LED panel, the re-growth layer is grown on the sidewall of the light-emitting layer and part of the second-type epitaxial layer.

In some exemplary embodiments or any combination of preceding exemplary embodiments of the micro LED panel, the re-growth layer on the sidewall of the light-emitting layer is not parallel to an extending direction of the light-emitting layer.

In some exemplary embodiments or any combination of preceding exemplary embodiments of the micro LED panel, an inclined angle of the re-growth layer on the sidewall of the light-emitting layer is 30 degrees to 90 degrees relative to an extending direction of the light-emitting layer; and the re-growth layer extruded into the dielectric layer is parallel to the bottom surface of the second-type epitaxial layer.

In some exemplary embodiments or any combination of preceding exemplary embodiments of the micro LED panel, the re-growth layer extruded into the dielectric layer is connected to an adjacent light-emitting layer and an adjacent second-type epitaxial layer of an adjacent micro LED structure.

In some exemplary embodiments or any combination of preceding exemplary embodiments of the micro LED panel, diameter of the mesa structure is not more than 3 μm.

In some exemplary embodiments or any combination of preceding exemplary embodiments of the micro LED panel, the light-emitting layer comprises a top surface, an edge surface and a bottom surface; and, the re-growth layer is grown on the edge surface of the light-emitting layer and not grown on the top surface and the bottom surface of the light-emitting layer.

In some exemplary embodiments or any combination of preceding exemplary embodiments of the micro LED panel, the light-emitting layer comprises a plurality of pairs of quantum wells; and the re-growth layer on the sidewall of the light-emitting layer is not parallel to surface of each of the plurality of pairs of quantum wells.

In some exemplary embodiments or any combination of preceding exemplary embodiments of the micro LED panel, the light-emitting layer has a straight-line shape without any bending.

In some exemplary embodiments or any combination of preceding exemplary embodiments of the micro LED panel, material of the re-growth layer with intrinsic doped ions is the same as the material of the first-type epitaxial layer and/or the material of the second-type epitaxial layer but without the intentional doping ions.

In some exemplary embodiments or any combination of preceding exemplary embodiments of the micro LED panel, material of the re-growth layer is selected from at least one of GaP, AlP, GaAs, InP, AlInP, GaInP, AlN, GaN, and/or InN.

In some exemplary embodiments or any combination of preceding exemplary embodiments of the micro LED panel, the material of the re-growth layer is monocrystal, the material of the first epitaxial layer is monocrystal, and the material of the second-type epitaxial layer is monocrystal.

In some exemplary embodiments or any combination of preceding exemplary embodiments of the micro LED panel, a band gap of the re-growth layer is greater than a band gap of the light-emitting layer.

In some exemplary embodiments or any combination of preceding exemplary embodiments of the micro LED panel, the thickness of the re-growth layer is less than the thickness of the light-emitting layer.

In some exemplary embodiments or any combination of preceding exemplary embodiments of the micro LED panel, the thickness of the re-growth layer is not more than 100 nm.

In some exemplary embodiments or any combination of preceding exemplary embodiments of the micro LED panel, the resistance of the re-growth layer is higher than the resistance of the light-emitting layer.

In some exemplary embodiments or any combination of preceding exemplary embodiments of the micro LED panel, the re-growth layer is not electrically conductive.

In some exemplary embodiments or any combination of preceding exemplary embodiments of the micro LED panel, the dielectric layer is further formed on the surface of the re-growth layer between the adjacent mesa structures.

In some exemplary embodiments or any combination of preceding exemplary embodiments of the micro LED panel, the material of the dielectric layer is one or more of SiO₂, SiNx, Al₂O₃, AlN, HfO₂, TiO₂, and/or ZrO₂, etc.

In some exemplary embodiments or any combination of preceding exemplary embodiments of the micro LED panel, the material of the first-type epitaxial layer is one or more of p-type GaAs, InGaAs, GaP, GaN, InGaN, AlGaN, AlInP, GaInP, and/or AlGaInP, etc.; and the material of the second-type epitaxial layer is one or more of n-type GaAs, InGaAs, GaP, GaN, InGaN, AlGaN, AlInP, GaInP, and/or AlGaInP, etc.

In another aspect of some exemplary embodiments, the present disclosure provides a method of manufacturing the micro LED panel, comprising:
step 1, supplying a semiconductor substrate with an epitaxial structure, wherein the epitaxial structure comprises a first-type epitaxial layer, a light-emitting layer, and a second-type epitaxial layer from the top down;
step 2, forming a mesa structure by patterning the epitaxial structure;
step 3, forming a first mask pattern on the semiconductor substrate to cover the sidewall of the first-type epitaxial layer and the sidewall of a light-emitting layer;
step 4, depositing a first dielectric layer on the substrate between the adjacent mesa structures, wherein the top of the first dielectric layer is not higher than bottom of the light-emitting layer; and then, removing the first mask pattern;
step 5, forming a second mask pattern on the semiconductor substrate to cover at least part of the sidewall and the top of the first-type epitaxial layer, and forming a re-growth layer on the sidewall of the light-emitting layer and on the top of the first dielectric layer by an epitaxial material re-growth process;
step 6, removing the second mask pattern;
step 7, forming a second dielectric layer on the re-growth layer and on the top and the sidewall of the first-type epitaxial layer and forming an opening in the second dielectric layer on the surface of the first-type epitaxial layer; and then, forming a bottom contact in the opening;
step 8, forming a bottom-connected structure in the opening;
step 9, bonding the first-type epitaxial layer and the bottom-connected structure with an IC backplane by turning the semiconductor substrate upside down; and then, removing the semiconductor substrate; and
step 10, forming a top contact and a top conductive layer on the second epitaxial layer.

In some exemplary embodiments or any combination of preceding exemplary embodiments of the method of manufacturing the micro LED panel, in step 5, the epitaxial material re-growth process comprises: the epitaxial layer is grown on the sidewall of the light-emitting layer and the epitaxial material is deposited on the surface of the mask pattern.

In some exemplary embodiments or any combination of preceding exemplary embodiments of the method of manufacturing the micro LED panel, in step 5, the temperature in the re-growth process is 400° C. to 1000° C., and the re-growth time is 5 seconds to 1000 seconds.

In another aspect of some exemplary embodiments, the present disclosure provides a micro LED panel, comprising: a micro LED structure array comprising at least one micro LED structure, wherein the micro LED structure comprises: a mesa structure, wherein the mesa structure from bottom to top comprises: a first-type epitaxial layer, a light-emitting layer, and a second-type epitaxial layer; and, a re-growth layer, grown on the whole sidewall of the second-type epitaxial layer and the whole sidewall of the light-emitting layer.

In some exemplary embodiments or any combination of preceding exemplary embodiments, the micro LED panel further includes a dielectric layer formed between adjacent micro LED structures; and a top end of the re-growth layer further extrudes along top surface of the dielectric layer.

In some exemplary embodiments or any combination of preceding exemplary embodiments of the micro LED panel, the re-growth layer on the sidewall of the light-emitting layer is not parallel to an extending direction of the light-emitting layer.

In some exemplary embodiments or any combination of preceding exemplary embodiments of the micro LED panel, an inclined angle of the re-growth layer on the sidewall of the light-emitting layer is 30 degrees to 90 degrees relative to an extending direction of the light-emitting layer; and the re-growth layer extruded along the dielectric layer is parallel to the top surface of the dielectric layer.

In some exemplary embodiments or any combination of preceding exemplary embodiments of the micro LED panel, the re-growth layer extruded along the top of the dielectric layer is connected to an adjacent light-emitting layer and a second-type epitaxial layer.

In some exemplary embodiments or any combination of preceding exemplary embodiments of the micro LED panel, diameter of the mesa structure is not more than 3 μm.

In some exemplary embodiments or any combination of preceding exemplary embodiments of the micro LED panel, the light-emitting layer comprises a top surface, an edge surface and a bottom surface; and the re-growth layer is grown on the edge surface of the light-emitting layer and not grown on the top surface and the bottom surface of the light-emitting layer.

In some exemplary embodiments or any combination of preceding exemplary embodiments of the micro LED panel, the light-emitting layer comprises a plurality of pairs of quantum wells; and the re-growth layer on the sidewall of the light-emitting layer is not parallel to surface of each of the plurality of pairs of quantum wells.

In some exemplary embodiments or any combination of preceding exemplary embodiments of the micro LED panel, the light-emitting layer has a straight-line shape without any bending.

In some exemplary embodiments or any combination of preceding exemplary embodiments of the micro LED panel, material of the re-growth layer with intrinsic doped ions is the same as material of the first-type epitaxial layer and/or material of the second-type epitaxial layer but without the intentional doping ions.

In some exemplary embodiments or any combination of preceding exemplary embodiments of the micro LED panel, the material of the re-growth layer is selected from at least one of GaP, AlP, GaAs, InP, AlInP, GaInP, AlN, GaN, and/or InN.

In some exemplary embodiments or any combination of preceding exemplary embodiments of the micro LED panel, the material of the re-growth layer is monocrystal, the material of the first epitaxial layer is monocrystal, and the material of the second epitaxial layer is monocrystal.

In some exemplary embodiments or any combination of preceding exemplary embodiments of the micro LED panel, a band gap of the re-growth layer is greater than a band gap of the light-emitting layer.

In some exemplary embodiments or any combination of preceding exemplary embodiments of the micro LED panel, the thickness of the re-growth layer is less than the thickness of the light-emitting layer.

In some exemplary embodiments or any combination of preceding exemplary embodiments of the micro LED panel, the thickness of the re-growth layer is not more than 100 nm.

In some exemplary embodiments or any combination of preceding exemplary embodiments of the micro LED panel, the resistance of the re-growth layer is higher than the resistance of the light-emitting layer.

In some exemplary embodiments or any combination of preceding exemplary embodiments of the micro LED panel, the re-growth layer is not electrically conductive.

In some exemplary embodiments or any combination of preceding exemplary embodiments of the micro LED panel, a dielectric layer is formed between adjacent micro LED structures and further formed on surface of the re-growth layer.

In some exemplary embodiments or any combination of preceding exemplary embodiments of the micro LED panel, the material of the dielectric layer is one or more of SiO₂, SiNx, Al₂O₃, AlN, HfO₂, TiO₂, and/or ZrO₂, etc.

In some exemplary embodiments or any combination of preceding exemplary embodiments of the micro LED panel, the material of the first-type epitaxial layer is one or more of p-type GaAs, InGaAs, GaP, GaN, InGaN, AlGaN, AlInP, GaInP, and/or AlGaInP; and the material of the second-type epitaxial layer is one or more of n-type GaAs, InGaAs, GaP, GaN, InGaN, AlGaN, AlInP, GaInP, and/or AlGaInP.

In another aspect of some exemplary embodiments, the present disclosure provides a method of manufacturing the micro LED panel, comprising:
step 1, supplying a semiconductor substrate with an epitaxial structure, wherein the epitaxial structure comprises a first-type epitaxial layer, a light-emitting layer, and a second-type epitaxial layer from the top down;
step 2, forming a mesa structure by patterning the epitaxial structure;
step 3, forming a mask pattern on the semiconductor substrate to cover the first-type epitaxial layer;
step 4, forming a re-growth layer on the sidewall of the light-emitting layer and the sidewall of the second-type epitaxial layer by an epitaxial material re-growth process;
step 5, removing the mask pattern;
step 6, forming a bottom contact on the surface of the first-type epitaxial layer and forming a dielectric layer on the re-growth layer and on the top and sidewall of the first-type epitaxial layer between adjacent mesa structures, wherein the dielectric layer has an opening exposing the top of the bottom contact;
step 7, forming a bottom-connected structure in the opening;
step 8, bonding the first-type epitaxial layer and the bottom-connected structure with an IC backplane by turning the semiconductor substrate upside down; and then, removing the semiconductor substrate; and
step 9, forming a top contact and a top conductive layer on the second epitaxial layer.

In some exemplary embodiments or any combination of preceding exemplary embodiments of the method of manufacturing the micro LED panel, in step 4, the re-growth layer is further formed on the semiconductor substrate between the adjacent mesa structures; and the temperature in the re-growth process is 400° C. to 1000° C., and the re-growth time is 5 seconds to 1000 seconds.

The micro LED panel provided by the present disclosure can avoid the nonradiative recombination at the sidewalls of the micro LED structure. Furthermore, compared with the conventional micro LEDs, the micro LED structure of the present disclosure has a high directional emission, with no other reflective structure, thereby simplifying the micro LED structure and decreasing the cost. Furthermore, the present disclosure can also inhibit the non-radiation recombination at the surface of the micro LED structures, thereby improving the image quality and increase the EQE of the pixels.

Note that the various embodiments described above can be combined with any other embodiments described herein. The features and advantages described in the specification are not all inclusive and, in particular, many additional features and advantages will be apparent to one of ordinary skill in the art in view of the drawings, specification, and claims. Moreover, it should be noted that the language used in the specification has been principally selected for readability and instructional purposes, and may not have been selected to delineate or circumscribe the inventive subject matter.

### BRIEF DESCRIPTION OF THE DRAWINGS

So that the present disclosure can be understood in greater detail, a more particular description may be had by reference to the features of various embodiments, some of which are illustrated in the appended drawings. The appended drawings, however, merely illustrate pertinent features of the present disclosure and are therefore not to be considered limiting, for the description may admit to other effective features.

For convenience, “up” is used to mean away from the substrate of a light emitting structure as shown in the Figures, “down” means toward the substrate, and other directional terms such as top, bottom, above, below, under, beneath, etc. are interpreted accordingly.

FIG. 1 is a sectional diagram of a micro LED structure according to some embodiments (for example, the first embodiment) of the present disclosure.

FIGS. 2-15 illustrate the steps of a method for manufacturing the micro LED structure in FIG. 1 according to some embodiments (for example, the first embodiment) of the present disclosure.

FIG. 16 is a sectional structure diagram of a micro LED panel according to some embodiments (for example, the second embodiment) of the present disclosure.

FIGS. 17˜23 illustrate the steps of a method for manufacturing the micro LED panel in FIG. 16 according to some embodiments (for example, the second embodiment) of the present disclosure.

FIG. 24 is a sectional structure diagram of a micro LED panel according to some embodiments (for example, the third embodiment) of the present disclosure.

FIGS. 25˜36 illustrate the steps of a method for manufacturing the micro LED panel in FIG. 24 according to some embodiments (for example, the third embodiment) of the present disclosure.

FIG. 37 is a sectional structure diagram of a micro LED panel according to some embodiments (for example, the fourth embodiment) of the present disclosure

FIGS. 38˜48 illustrate the steps of a method for manufacturing the micro LED panel in FIG. 37.

In accordance with common practice, the various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### DETAILED DESCRIPTION

Numerous details are described herein in order to provide a thorough understanding of the example embodiments illustrated in the accompanying drawings. However, some embodiments may be practiced without many of the specific details, and the scope of the claims is only limited by those features and aspects specifically recited in the claims. Furthermore, well-known processes, components, and materials have not been described in exhaustive detail so as not to unnecessarily obscure pertinent aspects of the embodiments described herein.

As discussed above, to resolve the problem in the related technologies, in some embodiments, a micro LED panel comprising multiple micro LED structures is disclosed in the present disclosure. The dimension of the micro LED panel is not more than 1 cm. The micro LED structures are formed in the micro LED panel in an array, with a resolution such as 720*480, 640*480, 1920*1080, 1280*720, 2 k, or 4 k. The diameter of the micro LED structure is at a nano-meter level, such as 20 nm to 100 nm.

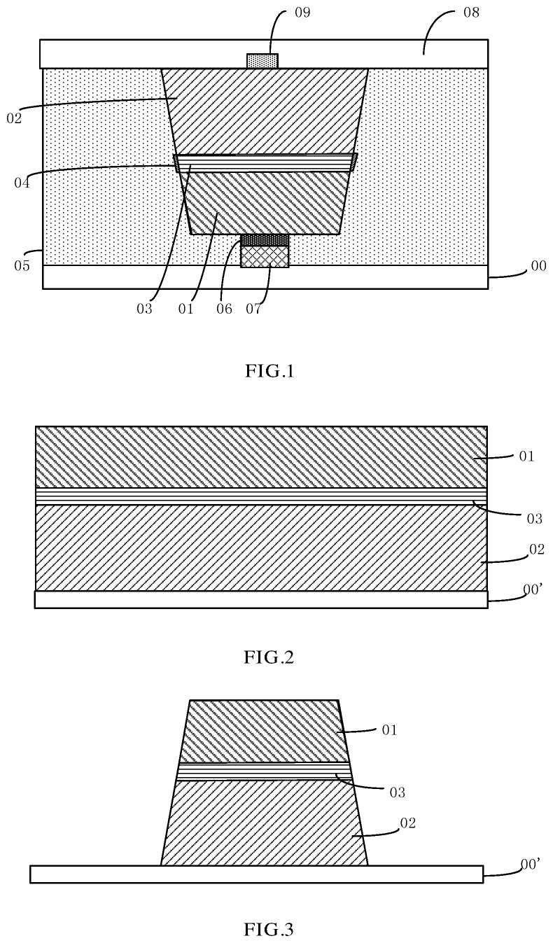

FIG. 1 is a sectional diagram of a micro LED structure according to some embodiments of the present invention. Referring to FIG. 1, the micro LED structure is formed by a first-type epitaxial layer 01, a light-emitting layer 03 and a second-type epitaxial layer 02 from bottom to top. The first type and the second type are different conductive types, for example, the first type is P type, while the second type is N type. In another example, the first type is N type, while the second type is P type. In some embodiments, the material of the first-type epitaxial layer 01 can be one or more of p-type GaAs, InGaAs, GaP, GaN, InGaN, AlGaN, AlInP, GaInP, AlGaInP, AlP, InP, AlN, and/or InN, etc., or any combinations thereof, preferably one or more of p-type GaAs, InGaAs, GaP, GaN, InGaN, AlGaN, AlInP, GaInP, and/or AlGaInP, or any combinations thereof, and the material of the second-type epitaxial layer 03 can be one or more of n-type GaAs, InGaAs, GaP, GaN, InGaN, AlGaN, AlInP, GaInP, AlGaInP, AlP, InP, AlN, and/or InN, etc., or any combinations thereof, preferably one or more of n-type GaAs, InGaAs, GaP, GaN, InGaN, AlGaN, AlInP, GaInP, and/or AlGaInP, or any combinations thereof.

In some embodiments, the light-emitting layer 03 is formed by multiple pairs of quantum well layers. The material of the quantum well layer can be one of GaAs, InGaAs, GaP, GaN, InGaN, AlGaN, AlInP, GaInP, AlGaInP, etc. Additionally, the thickness of the first-type epitaxial layer 01 is larger than the thickness of the second-type epitaxial layer 02 and the thickness of the light-emitting layer 03 is less than that of the first-type epitaxial layer 01. Preferably, the thickness of the first-type epitaxial layer 01 is 700 nm to 2 μm, the thickness of the second-type epitaxial layer 02 is 100 nm to 200 nm. Preferably, the thickness of a single quantum well layer is not more than 30 nm. In some examples, the light-emitting layer 03 includes not more than three pairs of quantum well layers.

In some embodiments, the first-type epitaxial layer 01 may have multiple stacked first-type epitaxial sub-layers, the second-type epitaxial layer 02 may have multiple stacked second-type epitaxial sub-layers. For example, the top layer of the first-type epitaxial sub-layer is a P cap layer connected to the bottom of the light-emitting layer 03, the bottom layer of the second-type epitaxial sub-layer is an N cap layer connected to the top of the light-emitting layer 03, for protecting the quantum well layers from being damaged.

Furthermore, the first-type epitaxial layer 01 comprises one or more reflective mirror layers 011 (not shown in FIG. 1) thereof. The reflective mirror layer(s) 011 can be formed at the bottom surface of the first-type epitaxial layer 01 or formed in the inner of the first-type epitaxial layer 01. The material of the reflective mirror layer is a combination of a dielectric material and a metal material. Furthermore, the dielectric material is SiO₂ or SiNx, wherein, x is a positive integer; and preferably, the metal material is Au or Ag. It is noted that, multiple reflective mirror layers 011 are horizontally formed in the first-type epitaxial layer 01 one by one in different horizontal levels, thereby dividing the first-type epitaxial layer 01 into multiple layers.

In some embodiments, the top contact 09 is formed at the top surface of the second-type epitaxial layer 02. The conductive type of the top contact 09 is the same as that of the second-type epitaxial layer 02, such as, the second type is n type, the top contact 09 is n type top contact; or, the second type is p type, the top contact 09 is p type top contact. In some embodiments, the top contact 09 is made by metal or metal alloy, such as, AuGe, AuGeNi, etc. The top contact 09 is used for forming ohmic contact between the top conductive layer 08 and the second-type epitaxial layer 02, so as to optimize the electrical property of the micro LEDs. The diameter of the top contact 09 is about 20 nm to 50 nm and the thickness of the top contact 09 is about 10 nm to 20 nm. In some embodiments, the top conductive layer 08 is transparent and electrically conductive, such as Indium tin oxide (ITO), Fluorine-doped Tin Oxide (FTO), etc.

In some embodiments, the bottom contact 06 is formed at the bottom surface of the first-type epitaxial layer 01. The conductive type of the bottom contact 06 is the same as that of the first-type epitaxial layer 01, such as, the first-type epitaxial layer 01 is P type, the bottom contact 06 is also P type. Furthermore, since the light emits upward or downward from the LED mesa structure consisting or comprising of the first-type epitaxial layer 01, the second-type epitaxial layer 02 and the light-emitting layer 03, so the diameter of the bottom contact 06 is larger than the diameter of the top contact 09, while the diameter of the top contact 09 can be as small as possible, therefore, the top contact 09 is also as a dot on the top surface of the second-type epitaxial layer 02. For example, the width of the top contact 09 is less than ⅕, ⅙, 1/10 or 1/20 of the width of the second-type epitaxial layer 02. In some embodiments, the diameter of the bottom contact 06 can also be equal to or smaller than the diameter of the top contact 09. A bottom-connected structure 07 is formed at the bottom of the bottom contact 06. The bottom-connected structure 07 is used for connecting with the bottom electrode such as the contact pad in an IC backplane. Furthermore, the diameter of the bottom-connected structure 07 is 20 nm to 1 μm. Preferably, the diameter of the bottom-connected structure 07 is 800 nm to 1 μm. Furthermore, the center of the bottom contact 06 is aligned with the center of the top contact 09 in the vertical direction. In some embodiments, the material of the bottom contact 06 and the bottom-connected structure 07 are transparent conductive material, such as ITO, or FTO, etc. Additionally, in some embodiments, the material of the bottom contact 06 and the bottom-connected structure 07 are not transparent. The material of the bottom contact 06 and the bottom-connected structure 07 can be conductive metal. Preferably, the material of the bottom contact 06 can be selected from at least one of Au, Zn, Be, Cr, Ni, Ti, Ag and Pt. The material of the bottom-connected structure 07 can be selected from at least one of Au, Zn, Be, Cr, Ni, Ti, Ag and Pt.

As shown in FIG. 1, the center of the bottom contact 06 is vertically aligned with the center of the first-type epitaxial layer 01. But, in another embodiment, the center of the bottom contact 06 is not vertically aligned with the center of the first-type epitaxial layer 01.

In some embodiments, to avoid the surface carrier loss and the non-radiative recombination at the sidewall of the mesa structure, a re-growth layer 04 by a re-growth process is formed on the sidewall of the light-emitting layer 03, even on the sidewall of the first-type epitaxial layer 01 and on the sidewall of the second-type epitaxial layer 02. For example, the re-growth layer can be grown on part of the sidewall of the light-emitting layer 03 or on the whole sidewall of the light-emitting layer. “Whole” means a substantial or entire portion. Furthermore, the re-growth layer 04 can be further formed on part of the first-type epitaxial layer 01 or the whole sidewall of the first-type epitaxial layer 01; and/or, the re-growth layer 04 can be further formed on part of the second-type epitaxial layer 02 or the whole sidewall of the second-type epitaxial layer 02.

The re-growth layer 04 on the sidewall of the light-emitting layer 03 is not parallel to the extending horizontal direction of the light-emitting layer 03 as shown in FIG. 1. Furthermore, the light-emitting layer 03 comprises a top surface, an edge surface and a bottom surface; and, the re-growth layer 04 is only grown on the edge surface of the light-emitting layer 03 but not grown on the top surface and the bottom surface of the light-emitting layer 03. Preferably, the inclined angle of the re-growth layer 04 on the sidewall of the light-emitting layer is 30° to 90° relative to the horizontal direction of the light-emitting layer 03. That is to say, the re-growth layer 04 is grown on the end surface of the light-emitting layer 03, not grown on the top and bottom of the light-emitting layer 03. Additionally, the light-emitting layer 03 comprises several pairs of quantum wells; the re-growth layer 04 is not parallel to the surface of each of the several pairs of quantum wells. Herein, the light-emitting layer 03 is a straight line without any bending. Preferably, the diameter of the mesa structure is not more than 3 μm.

Herein, the material of the re-growth layer 04 with intrinsic doped ions is the same as the material of the first type epitaxial layer 01 and/or the material of the second type epitaxial layer 02 but without intentional extrinsic doping ions. For example, when the materials of first type epitaxial layer 01 and the second type epitaxial layer 02 are the same, and the intentional ion doping levels for the material of first type epitaxial layer 01 and the material of the second type epitaxial layer 02 are different, the material of the re-growth layer 04 may be the same as the underlying first type epitaxial layer 01 and the material of the second type epitaxial layer 02 but without the intentional extrinsic doping ions. In another example, when the material of first type epitaxial layer 01 and the second type epitaxial layer 02 are not the same, and the intentional ion doping levels for the material of first type epitaxial layer 01 and the material of the second type epitaxial layer 02 are different, the material of the re-growth layer 04 may be the same as the first type epitaxial layer 01 or the material of the second type epitaxial layer 02 but without the intentional extrinsic doping ions. The light emitting layer is an active region of a PN-junction formed by the first type epitaxial layer 01 and the second type epitaxial layer 02, and can be considered as composed of the two materials of the first type epitaxial layer 01 and the second type epitaxial layer 02. In some embodiments, the portion of the material of the re-growth layer that covers the first type epitaxial layer 01 is the same as the underlying first type epitaxial layer 01 but without the extrinsic intentional doping of the first type epitaxial layer 01, and the portion of the material of the re-growth layer that covers the second type epitaxial layer 02 is the same as the underlying second type epitaxial layer 02 but without the extrinsic intentional doping of the second type epitaxial layer 02. In some embodiments, the re-growth layer 04 can have some intrinsic doping levels or without doping levels. In some embodiments, the material growth parameters, such as the ambient/gas pressure, the power, and the material for the re-growth process are the same or similar as that of the first type epitaxial layer 01 and/or second type epitaxial layer 02. The material of the re-growth layer 04 must be lattice matched with the light emitting layer 03, the first type epitaxial layer 01 and/or the second type epitaxial layer 02. Preferably, the material of the re-growth layer 04 is monocrystal, the material of the first epitaxial layer 01 is monocrystal and the material of the second epitaxial layer 02 is monocrystal. Furthermore, the material of the re-growth layer 04 is selected from at least one of one or more of GaAs, InGaAs, GaP, GaN, InGaN, AlGaN, AlInP, GaInP, AlGaInP, AlP, InP, AlN, and/or InN, etc., or any combinations thereof, preferably one or more of GaP, AlP, GaAs, InP, AlInP, GaInP, AlN, GaN, and/or InN, or any combinations thereof. In another embodiment, the material of the re-growth layer 04 is without intentional doping ions and is not the same as the material of the first type epitaxial layer or the material of the second type epitaxial layer 02.

The resistance of the re-growth layer 04 is higher than the resistance of the light-emitting layer 03 and the re-growth layer 04 is not electrically conductive, thereby ensuring the normal work of the micro LED structures, and stopping the carries spreading outside the light-emitting layer 03. Preferably, the band gap of the re-growth layer 04 is greater than the band gap of the light-emitting layer 03. Furthermore, the thickness of the re-growth layer 04 is less than the thickness of the light-emitting layer 03, preferably, the thickness of the re-growth layer 04 is not more than 10 nm or 100 nm. In another embodiments, the thickness of the re-growth layer 04 is equal to or more than the thickness of the light-emitting layer 03.

Hereinafter, the detail of the micro LED panel and the method of manufacturing the micro LED panel will be described in consistent with the figures.

### Embodiment 1

To resolve the problem in the related technologies, a micro LED panel is provided in the embodiments of the present disclosure.

The micro LED panel comprises a micro LED structures array. Referring to FIG. 1, the micro LED structures in the micro LED panel comprises: a mesa structure comprising 01, 02 and 03, a re-growth layer 04, a top contact 09, a top conductive layer 08, a bottom contact 06, a bottom-connected structure 07, an IC backplane 00 and a dielectric layer 05 between the adjacent mesa structures.

The mesa structure comprises: a first-type epitaxial layer 01, a light-emitting layer 02 and a second-type epitaxial layer 03 from bottom to top. The re-growth layer 04 is grown on the whole sidewall of the light-emitting layer 03. In some embodiments, the re-growth layer 04 can be grown on at least part or all of the sidewall of the second-type epitaxial layer 02 and the whole sidewall of the light-emitting layer 03. Furthermore, the re-growth layer 04 is very thin not more than 10 nm, such as 5 nm, so the re-growth layer 04 is transparent in some embodiments.

A dielectric layer 05 is formed between the adjacent mesa structures and on the surface of the re-growth layer 04.

The dielectric layer 05 is further formed at the bottom of the mesa structures. Herein, a bottom contact 06 is formed at the bottom of the first-type epitaxial layer 01 and a bottom-connected structure 07 is formed at the bottom of the bottom contact 06. The bottom-connected structure 07 is connected to an IC backplane 00. The IC backplane 00 separately control the turning-on or turning off of each of the micro LEDs and separately control the gray values of each of the micro LEDs. The IC backplane 00 is a conventional IC backplane, which will not described herein in detail. Preferably, the dielectric layer 05 can be transparent. The material of the dielectric layer 05 is one or more of SiO₂, SiNx, Al₂O₃, AlN, HfO₂, TiO₂, and/or ZrO₂, etc., or any combinations thereof. Additionally, the material of the dielectric layer 05 is transparent in some embodiments.

Additionally, the top contact 09 and the top conductive layer 08 are formed on the top of the second-type epitaxial layer 02. In some embodiments, the top conductive layer 08 is continuously formed on the whole micro LED panel in the embodiment. In another embodiment, the top conductive layer 08 is formed on the top contact 09 and part of the top surface of the second-type epitaxial layer 02.

In some embodiments, the method of manufacturing the aforementioned micro LED panel comprises the following steps:

FIGS. 2-15 illustrate the steps of a method for manufacturing the micro LED structure in FIG. 1 according to some embodiments (for example, embodiment 1) of the present disclosure.

Referring to FIG. 2, step 1 includes supplying a semiconductor substrate 00′ with an epitaxial structure.

Herein, the epitaxial structure comprises a first-type epitaxial layer 01, a light-emitting layer 03 and a second-type epitaxial layer 02 from top down. The material of the semiconductor substrate 00′ can be GaN, GaAs, etc. The epitaxial structure is grown on the substrate 00′.

Referring to FIG. 3, step 2 includes forming a mesa structure by patterning the epitaxial structure.

Herein, the epitaxial structure is etched from top down by a conventional plasma etching process.

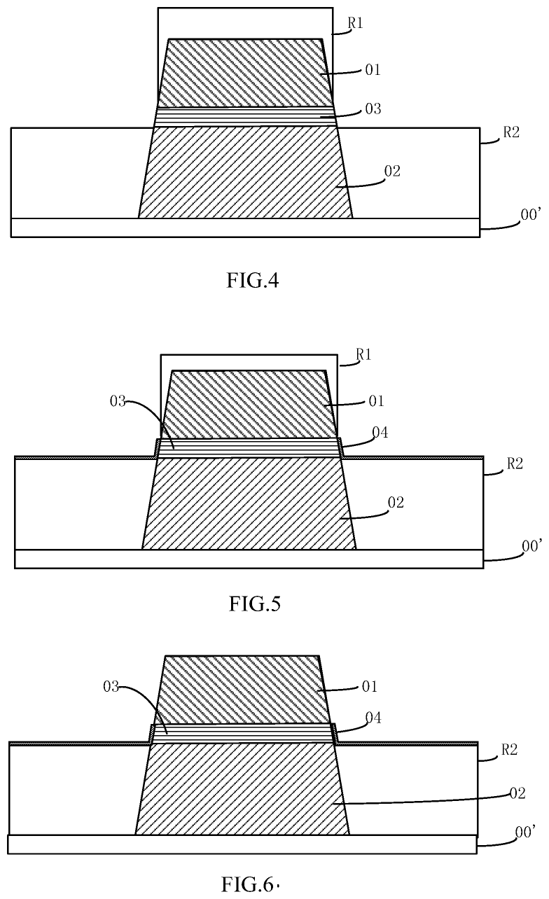

Referring to FIG. 4, step 3 includes forming a mask pattern R1, R2 on the semiconductor substrate 00′ to expose the sidewall of the light-emitting layer 03.

Herein, the mask pattern comprises a first mask pattern R1 covering the sidewall and the top of the first-type epitaxial layer 01 and a second mask pattern R2 covering the semiconductor substrate 00′ and at least part of the sidewall of the second epitaxial layer 02. The first mask pattern R1 and the second mask pattern R2 can be formed by controlling the exposure time in the exposure process. In some embodiments, the material of the first mask pattern R1 and the second mask pattern R2 is photoresist and R1 and R2 are formed by photolithography method. In another embodiment, the material of the first mask pattern R1 and the second mask pattern R2 can be another material such as dielectric material.

Referring to FIG. 5, step 4 includes forming a re-growth layer 04 on the sidewall of the light-emitting layer 03 by an epitaxial material re-growth process.

Herein, the re-growth layer 04 is grown on the sidewall of the light-emitting layer 03 and a layer of epitaxial material is deposited on the surface of the first mask pattern R1 and/or the second mask pattern R2. In this re-growth process, the temperature is 400° C. to 1000° C., and the re-growth time is 5 seconds to 1000 seconds. The material for the re-growth process is the same as the material of the first-type epitaxial layer 01 and/or the material of the second-type epitaxial layer 02 but without intentional doping ions.

In another embodiment, the bottom of the first mask pattern R1 is higher than the top of the light-emitting layer 03, so the re-growth layer 04 is further formed on part of the first-type epitaxial layer 01. Therefore, the position of the re-growth layer 04 is decided by the bottom position of the first mask pattern R1.

Yet in another embodiment, the top of the second mask pattern R2 is lower than the bottom of the light-emitting layer 03, so the re-growth layer 04 is further grown on at least part of the second-type epitaxial layer 02. Therefore, the position of the re-growth layer 04 is further decided by the top position of the second mask pattern R2.

Referring to FIG. 6, step 5 includes removing the mask pattern R1, and R2.

Herein, the first mask pattern R1 is removed by a conventional chemical etching process. The second mask pattern R2 cannot be etched in the chemical agent with the re-growth layer 04 covered.

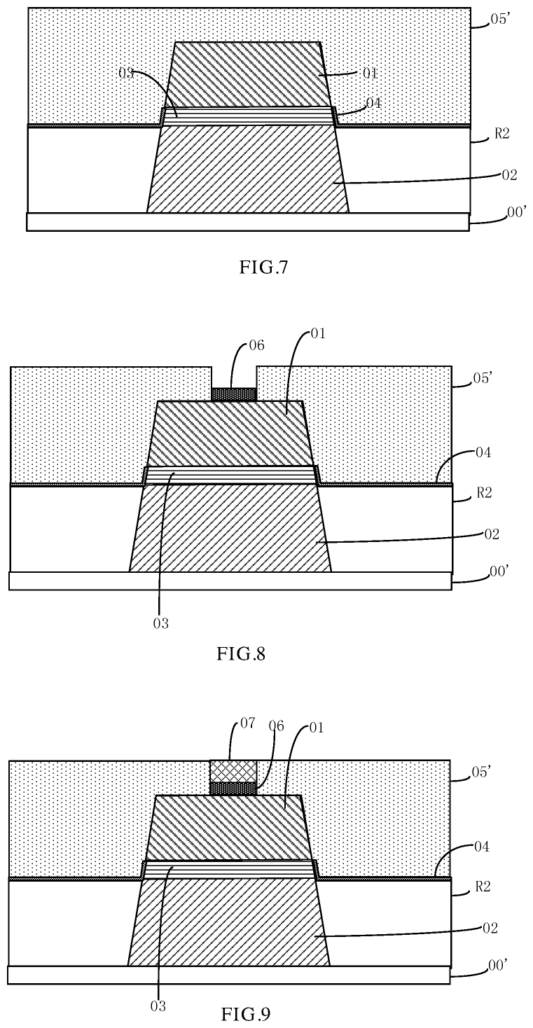

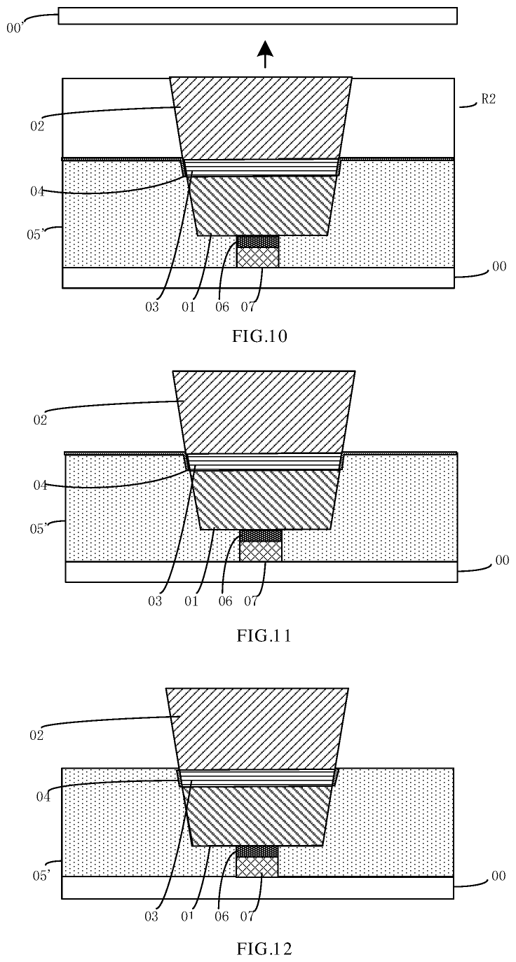

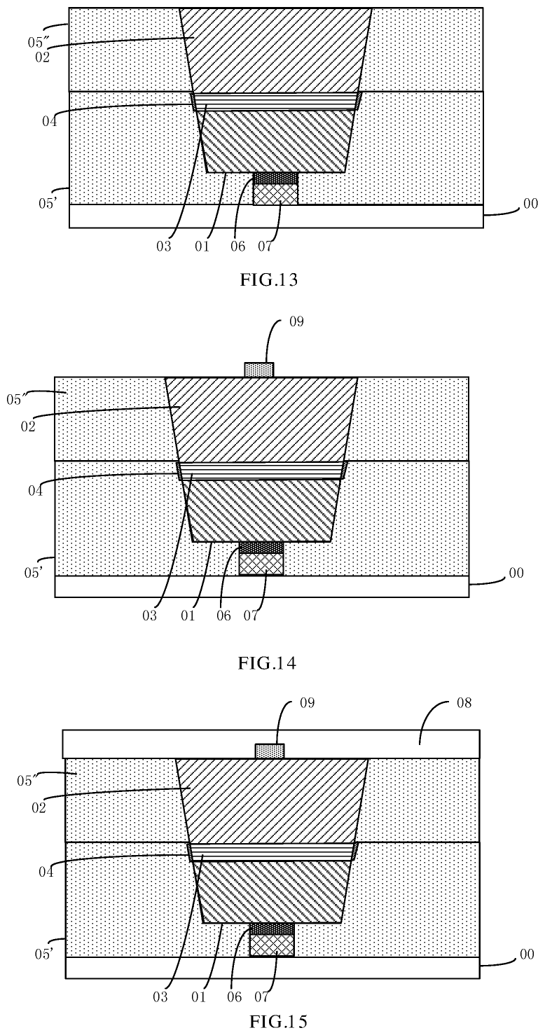

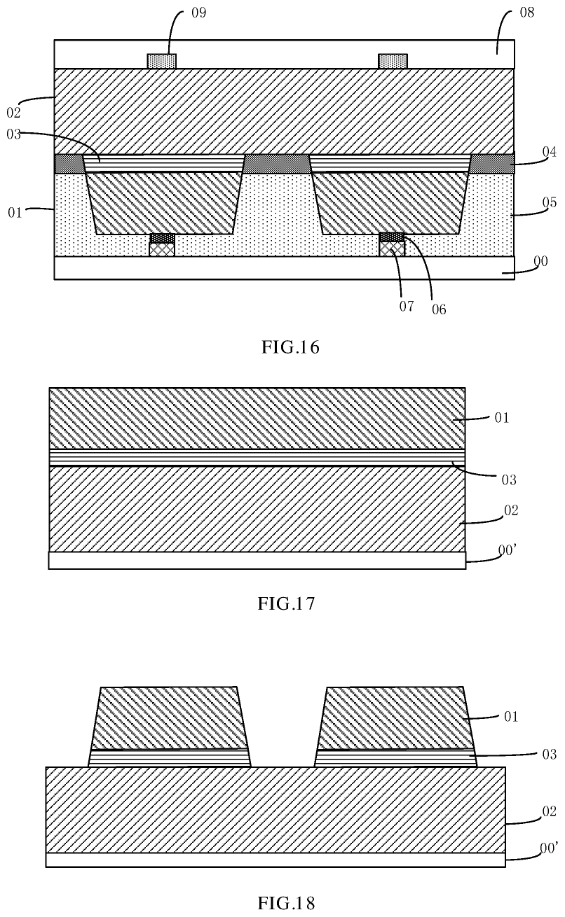

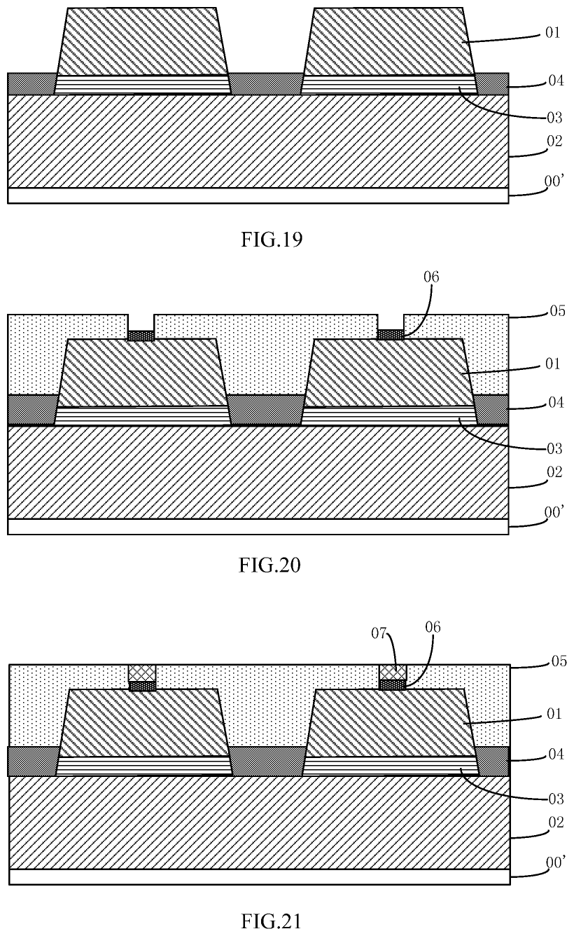

Referring to FIG. 7, step 6 includes depositing a first dielectric layer 05′ on the semiconductor substrate 00′ and, referring to FIG. 8, step 6 also includes forming an opening in the first dielectric layer 05′ on the surface of the first-type epitaxial layer 01. Step 6 further includes forming a bottom contact 06 in the opening.

Herein, a first dielectric layer 05′ is firstly deposited on the re-growth layer 04 by a chemical vapor deposition process. Then, an opening is formed in the first dielectric layer 05′on the top of the first-type epitaxial layer 01. Next, the bottom contact 06 is deposited into the opening and connected to the first-type epitaxial layer 01.

In some embodiments, the step 6 comprises the following steps: firstly, an initial dielectric layer is deposited on the re-growth layer 04, on the sidewall and the top of the first-type epitaxial layer 01. Then, the top of the initial dielectric layer is planarized to the top of the first-type epitaxial layer 01, and, the bottom contact 06 is deposited on the first-type epitaxial layer 01. Then, another dielectric layer is deposited on the initial dielectric layer and the sidewall and the top of the mesa structure, and covers the bottom contact 06, to form the first dielectric layer 05′. Next, an opening is formed in the first dielectric layer 05′and exposing the bottom contact 06.

In another embodiment, the bottom contact 06 can be formed before depositing the re-growth layer 04. Then, the re-growth layer 04 is deposited. Next, the first dielectric layer 05′ is formed on the re-growth layer 04. Finally, an opening is formed in the first dielectric layer 05′, to expose the bottom contact 06.

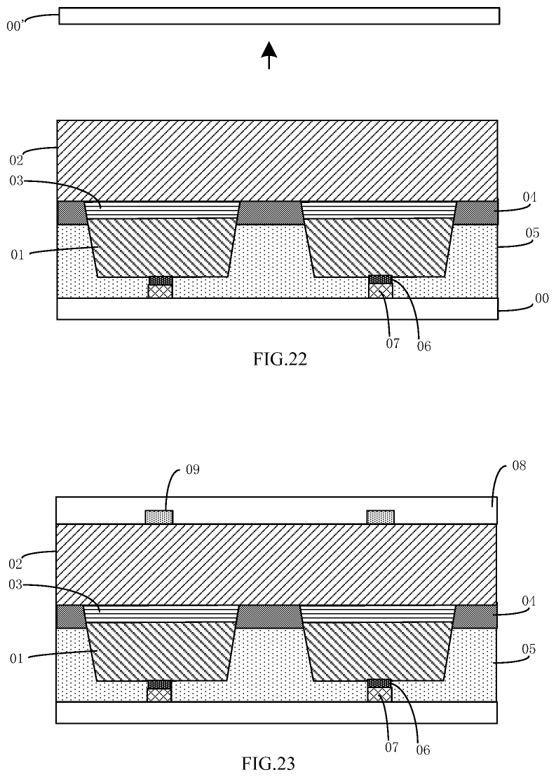

Referring to FIG. 9, step 7 includes forming a bottom-connected structure 07 in the opening.

Herein, the material of the bottom-connected structure 07 is deposited into the opening and on the bottom contact 06 by a conventional vapor deposition process.

Referring to FIG. 10, step 8 includes bonding the bottom-connected structure 07 with an IC backplane 00 after turning the semiconductor substrate 00′ upside down. Then, removing the semiconductor substrate 00′.

Herein, the semiconductor substrate 00′ with the epitaxial structure is firstly turned upside down. Then, the bottom-connected structure 07 is bonded with a pad of the IC backplane 00. After the bonding process, the semiconductor substrate 00′ is removed by a conventional removing process, such as a laser lift-off method.

Referring to FIG. 11, in step 9, the second mask pattern R2 is removed by a chemical etching method. Herein, after the semiconductor substrate 00′ is removed, the second mask pattern R2 is exposed into the air, so the second mask pattern R2 can be removed.

Referring to FIG. 12, in step 10, the epitaxial material formed by the re-growth process on the first dielectric layer 05′ is removed by a dry etching method.

Referring to FIG. 13, in step 11, a second dielectric layer 05″ is formed on the first dielectric layer 05′ and the top of the second dielectric layer 05″ is planarized by chemical mechanical polishing process.

Referring to FIGS. 14˜15, step 12 includes forming a top contact 09 and a top conductive layer 08 on the second-type epitaxial layer 02.

Herein, the top contact 09 is deposited on the top of the second-type epitaxial layer 02 with a mask protecting the other region, and then the mask is removed. Finally, a top conductive layer 08 is deposited on the second epitaxial layer 02 by a conventional vapor deposition process.

Referring to FIG. 1, herein, the dielectric layer 05 in FIG. 1 is formed by the first dielectric layer 05′ and the second dielectric layer 05″.

### Embodiment 2

The micro LED panel of embodiment 2 comprises a micro LED structure array. FIG. 16 is a sectional structure diagram of a micro LED panel according to some embodiments of the present disclosure.

Referring to FIG. 16, the micro LED structure in the micro LED panel comprises: a mesa structure, a continuous second-type epitaxial layer 02, a re-growth layer 04, a bottom contact 06, a bottom-connected structure 07, an IC backplane 00, a top contact 09 and a top conductive layer 08.

The mesa structure in this embodiment comprises the first-type epitaxial layer 01, the light-emitting layer 03 from bottom to top, but does not comprise the second-type epitaxial layer 02. The second-type epitaxial layer 02 is continuously formed on the top of the whole micro LED panel. Furthermore, the second-type epitaxial layer 02 is continuously formed on the top of the light-emitting layer 03 and the top of the re-growth layer 04.

In some embodiments, the re-growth layer 04 is like a ring around the mesa structure. The re-growth layer 04 is grown on the whole sidewall of the light-emitting layer 03; furthermore, the re-growth layer 04 is fully filled between the adjacent light-emitting layers 03. That is to say, the re-growth layer 04 is fully filled in the space between the adjacent light-emitting layers 03. In some embodiments, the re-growth layer 04 can be formed at the whole sidewall of the light-emitting layer 03 or part of the sidewall of the light-emitting layer 03 herein. Preferably, the re-growth layer 04 can be formed at the whole sidewall of the light-emitting layer 03. Furthermore, the bottom of the re-growth layer 04 is aligned with the bottom of the light-emitting layer 03, the top of the re-growth layer 04 is aligned with the top of the light-emitting layer 03. Furthermore, the top width of the re-growth layer 04 is the same as the top space width between the adjacent light-emitting layers 03. Furthermore, the re-growth layer 04 is very thin such as 5 nm, so the re-growth layer 04 is transparent in some embodiments.

In some embodiments, a dielectric layer 05 is formed at the bottom of the re-growth layer 04 between the adjacent mesa structures. Preferably, the material of the dielectric layer is one or more of SiO₂, SiNx, Al₂O₃, AlN, HfO₂, TiO₂, and/or ZrO₂, etc. The dielectric layer 05 is further formed at the bottom of the mesa structure. A bottom contact 06 is formed at the bottom of the mesa structure. A bottom-connected structure 07 is formed in the dielectric layer 05 at the bottom of the bottom contact 06 and is electrically connected to the first-type epitaxial layer 01. Additionally, the material of the dielectric layer 05 is transparent in some embodiments.

Additionally, the top contact 09 and the top conductive layer 08 are formed on the top of the second-type epitaxial layer 02. In some embodiments, the top conductive layer 08 is continuously formed on the whole micro LED panel. In another embodiment, the top conductive layer 08 is formed on the top contact 09 and part of the top surface of the second-type epitaxial layer 02.

The method of manufacturing the aforementioned micro LED panel in this embodiment 2 comprises the following steps:

FIGS. 17˜23 illustrate the steps of a method for manufacturing the micro LED panel in FIG. 16 according to some embodiments (for example, embodiment 2) of the present disclosure.

Referring to FIG. 17, step 1 includes supplying a semiconductor substrate 00′ with an epitaxial structure; and the epitaxial structure comprises a first-type epitaxial layer 01, a light-emitting layer 03 and a second-type epitaxial layer 02 from top down.

Herein, the epitaxial structure comprises a first-type epitaxial layer 01, a light-emitting layer 03 and a second-type epitaxial layer 02 from top down. The material of the semiconductor substrate 00′ can be GaN, GaAs, etc., on which the epitaxial structure is grown.

Referring to FIG. 18, step 2 includes forming a mesa structure by patterning the first-type epitaxial layer 01 and the light-emitting layer 03.

Herein, the first-type epitaxial layer 01 and the light-emitting layer 03 are etched from top down by a conventional plasma etching process.

In some embodiments, in the etching process of step 2, when the second-type epitaxial layer 02 is etched a certain depth, the re-growth layer 04 may be further formed on part of the sidewall of the second-type epitaxial layer 02. Therefore, the position of the re-growth layer 04 is decided by the etch depth in this step 2.

Referring to FIG. 19, step 3 includes forming a re-growth layer 04 on the whole sidewall of the light-emitting layer 03 by an epitaxial material re-growth process.

Herein, the re-growth layer 04 is grown on the sidewall of the light-emitting layer 03 and on the top surface of the second-type epitaxial layer 02 in FIG. 19 with a mask covering the sidewall and the top of the first-type epitaxial layer 01 (not shown in FIG. 19). In this re-growth process, the temperature is 400° C. to 1000° C., and the re-growth time is 5 seconds to 1000 seconds. The material for re-growth process is the same as the material of the first-type epitaxial layer 01 and/or the material of the second-type epitaxial layer 02 but without intentional doping ions.

Referring to FIG. 20, step 4 includes forming a dielectric layer 05 on the re-growth layer 04 and forming an opening in the dielectric layer 05 on the first-type epitaxial layer 01, and, forming a bottom contact 06 in the opening on the surface of the first-type epitaxial layer 01.

Herein, a dielectric layer 05 is firstly deposited on the re-growth layer 04, on the sidewall and the top of the first-type epitaxial layer 01. Then, an opening is formed in the dielectric layer 05 on the first-type epitaxial layer 01. Next, the bottom contact 06 is formed in the opening and connected to the first-type epitaxial layer 01.

In some embodiments, the step 4 comprises the following steps: firstly, an initial dielectric layer 05-01 (not shown in FIGs) is deposited on the re-growth layer 04, on the sidewall and the top of the first-type epitaxial layer 01. Then, the top of the initial dielectric layer 05-01 is planarized to the top of the first-type epitaxial layer 01; and, the bottom contact 06 is deposited on the first-type epitaxial layer 01. Then, another dielectric layer 05-02 (not shown in FIGs) is deposited on the initial dielectric layer and the sidewall and the top of the mesa structure, and covers the bottom contact 06, to form the completed dielectric layer 05. Next, an opening is formed in the dielectric layer 05 and exposing the bottom contact 06.

Referring to FIG. 21, step 5 includes forming a bottom-connected structure 07 in the opening.

Herein, the material of the bottom-connected structure 07 is deposited into the opening and on the bottom contact 06 by a conventional vapor deposition process.

Referring to FIG. 22, step 6 includes bonding the bottom-connected structure 07 with an IC backplane 00 by turning the semiconductor substrate 00′ upside down, then, removing the semiconductor substrate 00′.

Herein, the semiconductor substrate 00′ with the epitaxial structure is firstly turned upside down. Then, the bottom-connected structure 07 is bonded with a pad of the IC backplane 00. After the bonding process, the semiconductor substrate 00 is removed by a conventional removing process, such as a laser lift-off method.

Referring to FIG. 23, step 7 includes forming a top contact 09 and a top conductive layer 08 on the second epitaxial layer 02.

Herein, the top contact 09 is deposited on the top of the second-type epitaxial layer 02 with a mask protecting the other region. Then, a top conductive layer 08 is deposited on the second epitaxial layer 02 by a conventional vapor deposition process.

### Embodiment 3

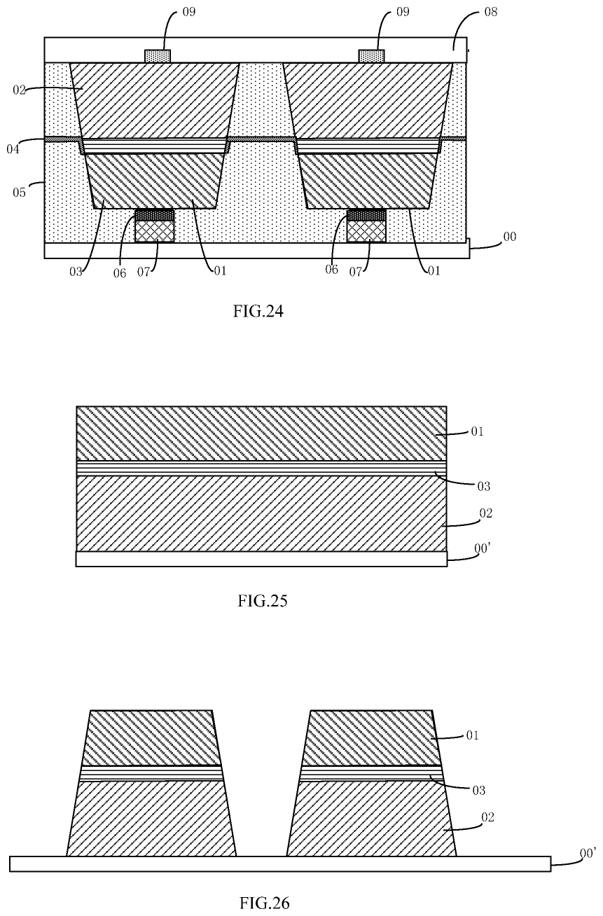

The micro LED panel of embodiment 3 comprises a micro LED structure array. FIG. 24 is a sectional structure diagram of a micro LED panel according to some embodiments (for example, the embodiment 3) of the present disclosure.

Referring to FIG. 24, the micro LED structure in the micro LED panel comprises: a mesa structure, a re-growth layer 04, a bottom contact 06, a bottom-connected structure 07, an IC backplane 00, a top contact 09 and a top conductive layer 08. A dielectric layer 05 is formed between the adjacent mesa structures.

The mesa structure from bottom to top consists of or comprises: a first-type epitaxial layer 01, a light-emitting layer 03 and a second-type epitaxial layer 02. The re-growth layer 04 is grown at least on the sidewall of the light-emitting layer 03. Furthermore, in another embodiment, the re-growth layer 04 is grown at the whole sidewall of the light-emitting layer 03 and at least part of the second-type epitaxial layer 02. The top end of the re-growth layer 04 further extrudes into the dielectric layer 05. The part of the re-growth layer 04 which is extruded into the dielectric layer 05 is parallel to the bottom surface of the second-type epitaxial layer 02. Additionally, the top end of the re-growth layer 04 extruded into the dielectric layer 05 is connected to the adjacent light-emitting layers 03 and the adjacent second-type epitaxial layers 02. Furthermore, the re-growth layer 04 is very thin not more than 10 nm, such as 5 nm, so the re-growth layer 04 is transparent in some embodiments.

Furthermore, the dielectric layer 05 is formed on the surface of the re-growth layer 04 between the adjacent mesa structures. Preferably, the material of the dielectric layer 05 is one or more of SiO₂, SiNx, Al₂O₃, AlN, HfO₂, TiO₂, and/or ZrO₂, etc. The dielectric layer 05 is further formed at the bottom of the mesa structures. An opening is formed in the dielectric layer 05. A bottom contact 06 is formed in the opening at the bottom of the first-type epitaxial layer 01. And, a bottom-connected structure 07 is formed in the opening and at the bottom of the first-type epitaxial layer 01. Additionally, the material of the dielectric layer 05 is transparent in some embodiments.

Additionally, the top contact 09 and the top conductive layer 08 are formed on the top of the second-type epitaxial layer 02. In some embodiments, the top conductive layer 08 is continuously formed on the whole micro LED panel. In another embodiment, the top conductive layer 08 is formed on the top contact 09 and part of the top surface of the second-type epitaxial layer 02.

The method of manufacturing the aforementioned micro LED panel in the embodiment 3, comprises the following steps:

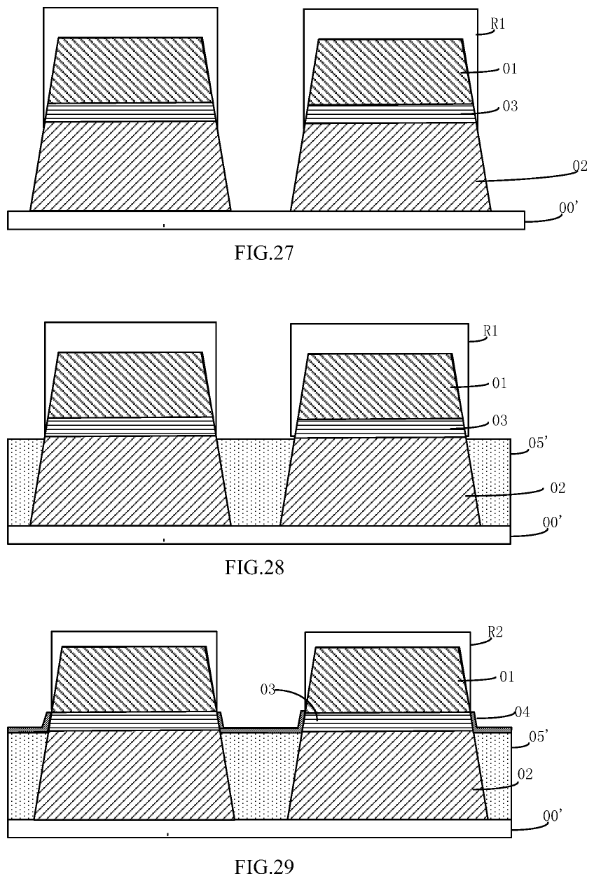

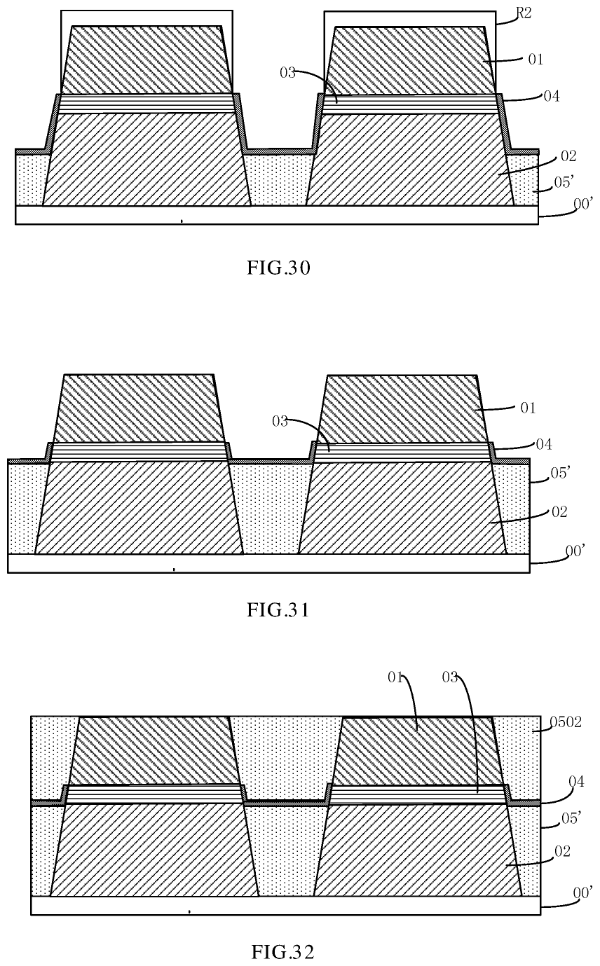

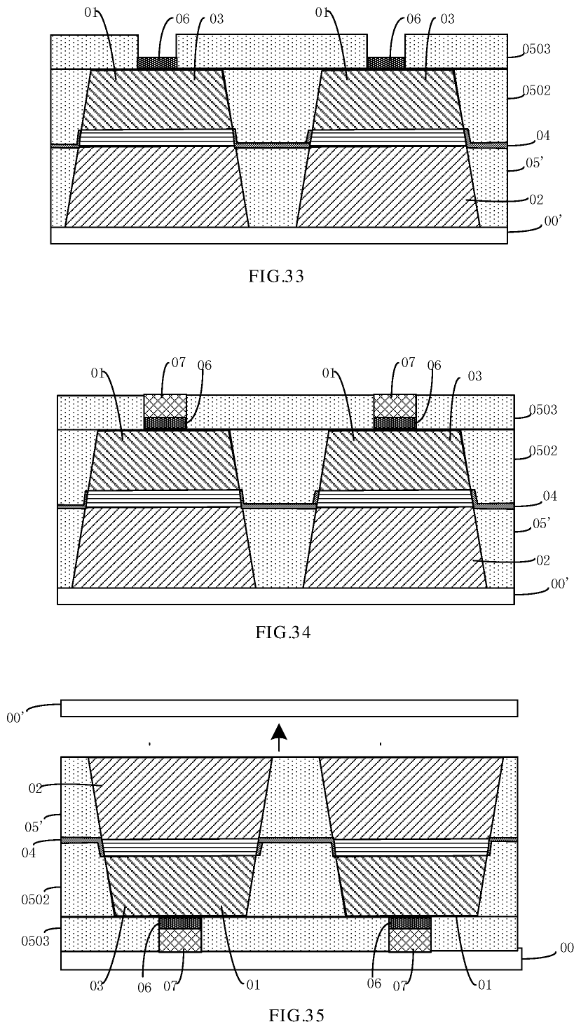

FIGS. 25˜36 illustrate the steps of a method for manufacturing the micro LED panel in FIG. 24 according to some embodiments (for example, the third embodiment) of the present disclosure.

Referring to FIG. 25, step 1 includes supplying a semiconductor substrate 00′ with an epitaxial structure.

Herein, the epitaxial structure comprises a first-type epitaxial layer 01, a light-emitting layer 03 and a second-type epitaxial layer 02 from top down. The material of the semiconductor substrate 00′ can be GaN, GaAs, etc., on which the epitaxial structure is grown.

Referring to FIG. 26, step 2 includes forming a mesa structure by patterning the epitaxial structure.

Herein, the epitaxial structure is etched from top down by a conventional plasma etching process.

Referring to FIG. 27, step 3 includes forming a first mask pattern R1 on the semiconductor substrate 00′ to cover the sidewall of the first-type epitaxial layer 01 and the light-emitting layer 03.

Herein, the first mask pattern R1 is formed covering the sidewall of the light-emitting layer 03, the sidewall and the top of the first-type epitaxial layer 01 by a photolithography method. The material of the first mask pattern R1 is photo resist. In another embodiment, the material of the first mask pattern R1 can be another material such as dielectric material.

Referring to FIG. 28, step 4 includes forming a first mask pattern R1, depositing a first dielectric layer 05′ on the substrate between the adjacent mesa structures,

[symbol]

Herein, under the protection of a first mask pattern R1, the first dielectric layer 05′ is deposited on the semiconductor substrate 00′ and on the surface of the first mask pattern R1 by a conventional vapor deposition process. The top of the first dielectric layer 05′ is aligned with the bottom of the light-emitting layer 03.

Then, after depositing the first dielectric layer 05′, the first mask pattern R1 is removed by a conventional chemical etching method.

Referring to FIG. 29, step 5 includes forming a second mask pattern R2 on the semiconductor substrate 00′ to cover the sidewall of the first-type epitaxial layer 01, and forming a re-growth layer 04 on the sidewall of the light-emitting layer 03 and on the top of the first dielectric layer 05′ by an epitaxial material re-growth process.

Herein, the second mask pattern R2 is firstly formed covering the sidewall of the first-type epitaxial layer 01. Then, the re-growth layer 04 is grown on the sidewall of the light-emitting layer 03 and deposited on the first dielectric layer 01. In this re-growth process, the temperature is 400° C. to 1000° C., and the re-growth time is 5 seconds to 1000 seconds. The material for re-growth process is the same as the material of the first-type epitaxial layer and/or the material of the second-type epitaxial layer but without intentional doping ions.

In another embodiment, referring to FIG. 30, the bottom of the first mask pattern R1 is lower than the bottom of the light-emitting layer 03, so the top of the first dielectric layer 01 is lower than the bottom of the light-emitting layer 03, and the re-growth layer 04 is further formed at least part of the sidewall of the second-type epitaxial layer 02. Therefore, the top position of the first dielectric layer 05′ is decided by the bottom position of the first mask pattern R1, and the position of the re-growth layer 04 is decided by the top position of the first dielectric layer 05′.

In some embodiments, when the bottom of the second mask pattern R2 is higher than the top of the light-emitting layer 03, the re-growth layer 04 is further formed on part of the sidewall of the first-type epitaxial layer 01. Therefore, the position of the re-growth layer 04 is further decided by the bottom position of the second mask pattern R2.

Referring to FIG. 31, step 6 includes removing the second mask pattern R2.

Herein, the second mask pattern R2 is removed by a conventional chemical etching process.

Referring to FIG. 32 and FIG. 33, step 7 includes forming a second dielectric layer on the re-growth layer 04 and the top and sidewall of the first-type epitaxial layer 01 and forming an opening in the second dielectric layer on the surface of the first-type epitaxial layer 01. And, a bottom contact 06 is formed in the opening.

Herein, the step 7 comprises the following steps: firstly, referring to FIG. 32, an initial dielectric layer 0502 is deposited on the re-growth layer 04, on the sidewall and the top of the first-type epitaxial layer 01. Then, the top of the initial dielectric layer 0502 is planarized to the top of the first-type epitaxial layer 01; and, referring to FIG. 33, the bottom contact 06 is deposited on the first-type epitaxial layer 01. Then, another dielectric layer 0503 is deposited on the initial dielectric layer 0502 and on the sidewall and the top of the mesa structure, and covers the bottom contact 06, to form the second dielectric layer. Next, an opening is formed in the dielectric layer 0503, and exposing the bottom contact 06. The second dielectric layer is formed by the initial dielectric layer 0502 and the other dielectric layer 0503.

In some embodiments, the second dielectric layer comprises a single dielectric layer as the combination of 0502 and 0503. The second dielectric layer is deposited on the surface of the re-growth layer 04, on the sidewall and the top of the first-type epitaxial layer 01, and on the top of the first dielectric layer 05′ by a conventional chemical vapor deposition process. Then, an opening is formed in the second dielectric layer on the top of the first-type epitaxial layer 01. Next, the bottom contact 06 is deposited into the opening and connected to the first-type epitaxial layer 01.

Referring to FIG. 34, step 8 includes forming a bottom-connected structure 07 in the opening.

Herein, the material of the bottom-connected structure 07 is deposited into the opening and on the bottom contact 06 by a conventional vapor deposition process.

Referring to FIG. 35, step 9 includes bonding the first-type epitaxial layer 01 and the bottom-connected structure 07 with an IC backplane 00 by turning the semiconductor substrate 00′ upside down, then, removing the semiconductor substrate 00′.

Herein, the semiconductor substrate 00′ with the epitaxial structure is firstly turned upside down; then, the bottom-connected structure 07 is bonded with a pad of the IC backplane 00. After the bonding process, the semiconductor substrate 00′ is removed by a conventional removing process, such as a laser lift-off method.

Referring to FIG. 36, step 10 includes forming a top contact 09 and a top conductive layer 08 on the second epitaxial layer 02.

Herein, the top contact 09 is deposited on the top of the second-type epitaxial layer 02 with a mask protecting the other region. Then, a top conductive layer 08 is deposited on the second epitaxial layer 02 by a conventional vapor deposition process.

### Embodiment 4

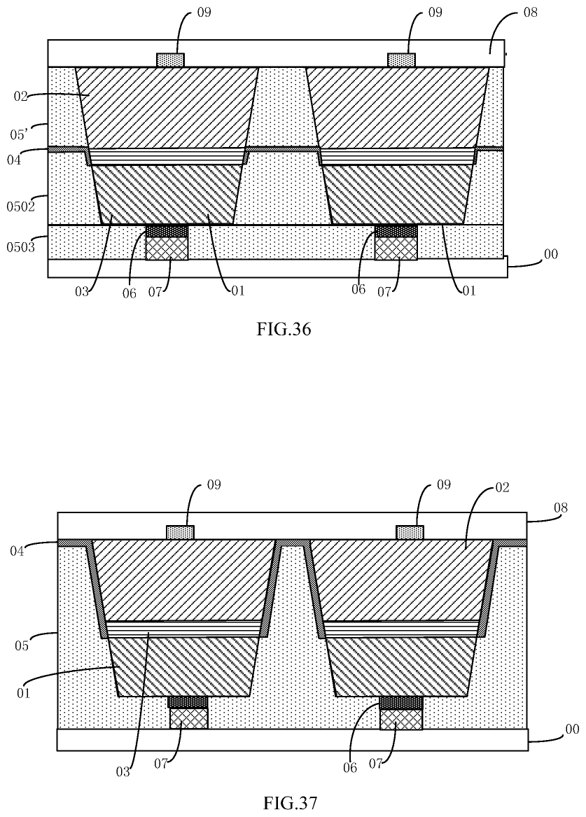

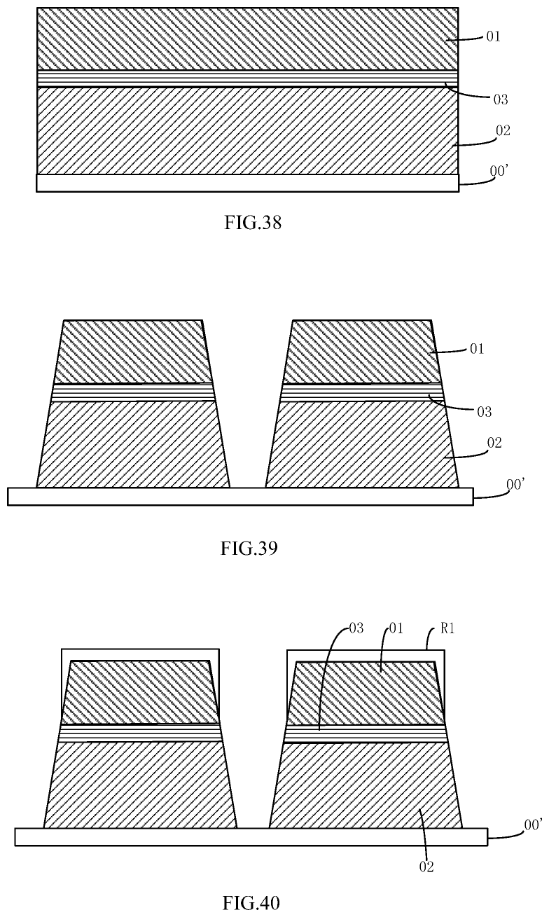

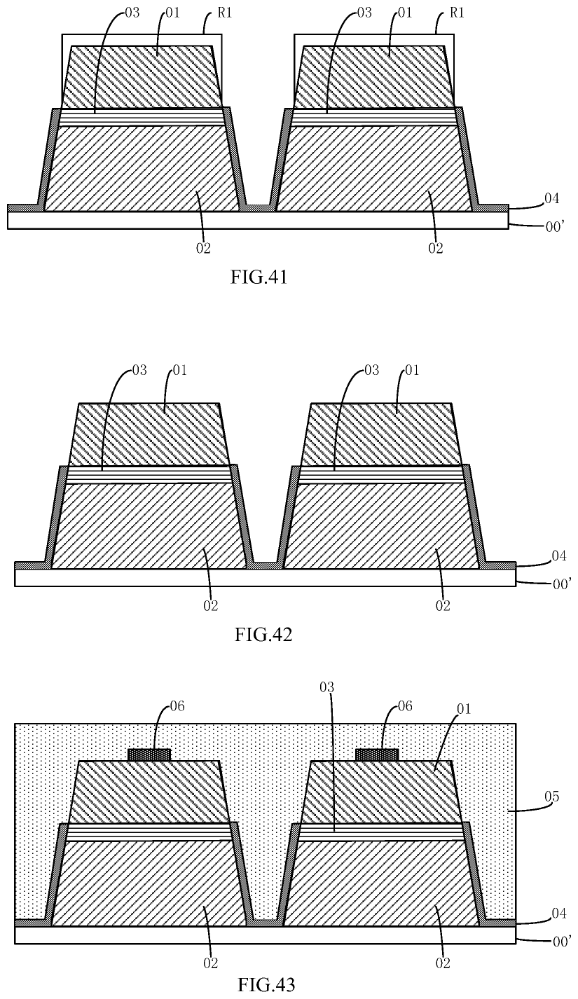

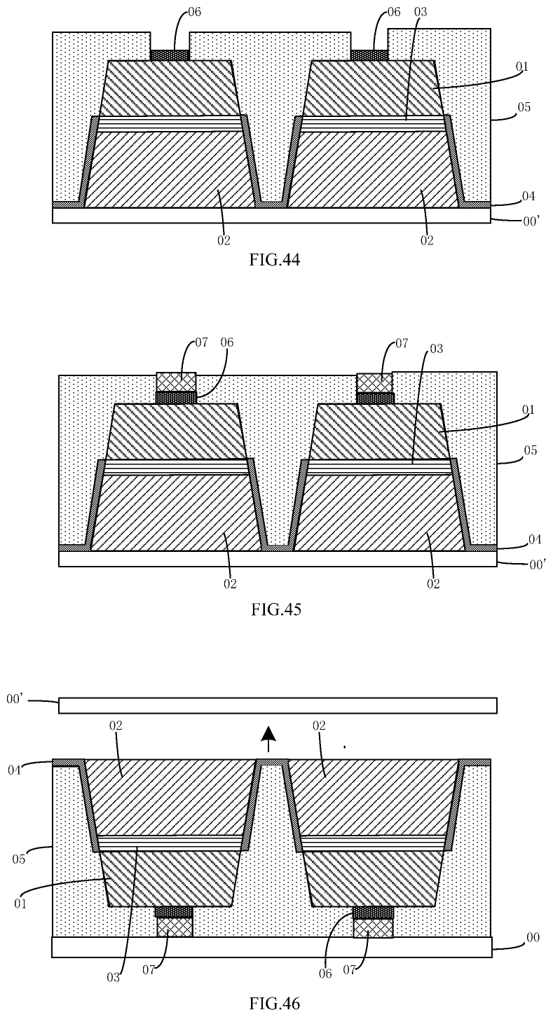

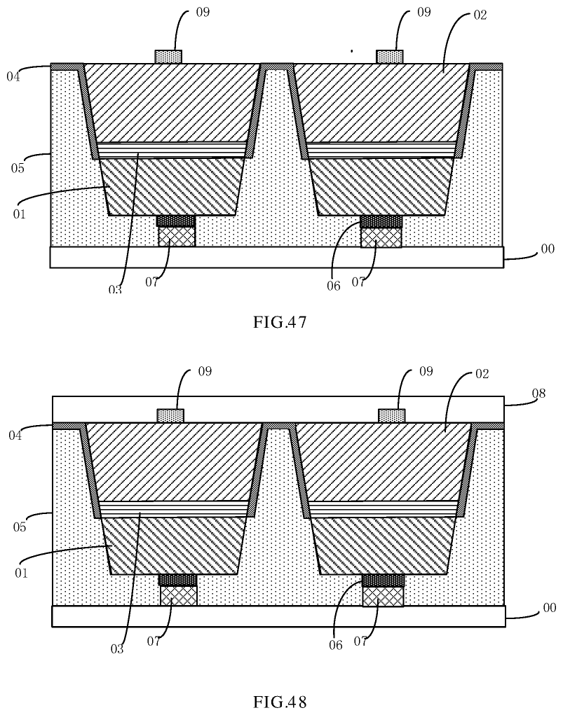

The micro LED panel of embodiment 4 comprises a micro LED structure array. FIG. 37 is a sectional structure diagram of a micro LED panel according to some embodiments (for example, the embodiment 4) of the present disclosure.

Referring to FIG. 37, The micro LED structure in the micro LED panel comprises: a mesa structure, a re-growth layer 04, a bottom contact 06, a bottom-connected structure 07, an IC backplane 00, a top contact 09 and a top conductive layer 08. Furthermore, a dielectric layer 05 is formed between the adjacent mesa structures. Herein, the material of the dielectric layer 05 is one or more of SiO₂, SiNx, Al₂O₃, AlN, HfO₂, TiO₂, and/or ZrO₂, etc. In another embodiments, the re-growth layer 04 is filled between the adjacent light-emitting layers 03 and the second-type epitaxial layer 02, like a ring around the mesa structure.

The mesa structure from bottom to top consists of or comprises: a first-type epitaxial layer 01, a light-emitting layer 03 and a second-type epitaxial layer 02. The re-growth layer 04 is grown on the whole sidewall of the second-type epitaxial layer 02 and the whole sidewall of the light-emitting layer 03. Herein, the top end of the re-growth layer 04 further extrudes along the top surface of the dielectric layer 05. The inclined angle of the part of the re-growth layer 04 which is on the sidewall of the light-emitting layer 03 is 30° to 90° relative to the light-emitting layer 03 horizontal extending direction. The part of the re-growth layer 04 which is extruded along the dielectric layer 05 is parallel to the top surface of the dielectric layer 05. Additionally, the re-growth layer 04 extruded along the top of the dielectric layer 05 is connected to the adjacent light-emitting layers 03 and the second-type epitaxial layer 02. Furthermore, the re-growth layer 04 is very thin not more than 10 nm, such as 5 nm, so the re-growth layer 04 is transparent in some embodiments. Additionally, the material of the dielectric layer 05 is transparent in some embodiments.

Herein, the top of the re-growth layer 04 is aligned with the top of the second-type epitaxial layer 02, and, the bottom of the re-growth layer 04 is aligned with the bottom of the light-emitting layer 03. An opening is formed in the dielectric layer 05. A bottom contact 06 is formed in the opening at the bottom of the first-type epitaxial layer 01. And, a bottom-connected structure 07 is formed in the opening and formed at the bottom of the bottom contact 06. Furthermore, the bottom contact 06 and the bottom-connected structure 07 are formed in the dielectric layer 05.

Additionally, the top contact 09 and the top conductive layer 08 are formed on the top of the second-type epitaxial layer 02. In some embodiments, the top conductive layer 08 is continuously formed on the whole micro LED panel in the embodiment. In another embodiment, the top conductive layer 08 is formed on the top contact 09 and part of the top surface of the second-type epitaxial layer 02.

The method of manufacturing the aforementioned micro LED panel in embodiment 4 comprises the following steps:

FIGS. 38˜48 illustrate the steps of a method for manufacturing the micro LED panel in FIG. 37.

Referring to FIG. 38, step 1 includes supplying a semiconductor substrate 00′ with an epitaxial structure.

Herein, the epitaxial structure comprises a first-type epitaxial layer 01, a light-emitting layer 03 and a second-type epitaxial layer 02 from top down. The material of the semiconductor substrate 00′ can be GaN, GaAs, etc., on which the epitaxial structure is grown.

Referring to FIG. 39, step 2 includes forming a mesa structure by patterning the epitaxial structure.

Herein, the epitaxial structure is etched from top down by a conventional plasma etching process.

Referring to FIG. 40, step 3 includes forming a mask pattern R1 on the semiconductor substrate 00′ to cover the first-type epitaxial layer 01.

Herein, the mask pattern R1 is formed covering the sidewall and the top of the first-type epitaxial layer 01 by a photolithography method. The material of the mask pattern R1 is photo resist. In another embodiment, the material of the mask pattern R1 can be another material such as dielectric material.

In another embodiment, the bottom of the mask pattern R1 is higher than the bottom of the first-type epitaxial layer 01, so the re-growth layer 04 is further formed on part of the first-type epitaxial layer 01. Therefore, the position of the re-growth layer 04 is decided by the bottom position of the mask pattern R1.

Referring to FIG. 41, step 4 includes forming a re-growth layer 04 on the sidewall of the light-emitting layer 03 and the sidewall of the second-type epitaxial layer 02 by an epitaxial material re-growth process.

Herein, the re-growth layer 04 is grown on the sidewall of the light-emitting layer 03, on the sidewall of the second epitaxial layer 02, and on the exposed top surface of the semiconductor substrate 00′. In this re-growth process, the temperature is 400° C. to 1000° C., and the re-growth time is 5 seconds to 1000 seconds. The material for re-growth process is the same as the material of the first-type epitaxial layer and/or the material of the second-type epitaxial layer but without intentional doping ions.

In another embodiment, another mask pattern (not shown in FIGs) is formed on the exposed surface of the semiconductor substrate 00′ and part of the sidewall of the second-type epitaxial layer 02. Then, the re-growth layer 04 is formed at part of the sidewall of the second-type epitaxial layer 02. Therefore, the position of the re-growth layer 04 is further decided by the other mask pattern.

Referring to FIG. 41 and FIG. 42, step 5 includes removing the mask pattern R1.

Herein, the mask pattern R1 is removed by a conventional chemical etching process.

Referring to FIGS. 43 and 44, step 6 includes forming a bottom contact 06 on the surface of the first-type epitaxial layer 01 and forming a dielectric layer 05 on the re-growth layer 04 and on the top and sidewall of the first-type epitaxial layer 01 between the adjacent mesa structures; wherein, the dielectric layer 05 has an opening exposing the top of the bottom contact 06;

Herein, referring to FIG. 43, step 6 includes forming a bottom contact 06 on the surface of the first-type epitaxial layer; then, the dielectric layer 05 is deposited on the surface of the re-growth layer 04, on the sidewall, the top of the first-type epitaxial layer 01, and the top of the bottom contact 06 by a conventional chemical vapor deposition process. Then, referring to FIG. 44, an opening is formed in the dielectric layer 05 on the top of the first-type epitaxial layer 01 by a dry etching process, to expose the bottom contact 06.

In some embodiments, the step 6 comprises the following steps: firstly, an initial dielectric layer is deposited on the re-growth layer, on the sidewall and the top of the first-type epitaxial layer. Then, the top of the initial dielectric layer is planarized to the top of the first-type epitaxial layer, and, the bottom contact is deposited on the first-type epitaxial layer. Then, another dielectric layer is deposited on the initial dielectric layer and on the sidewall and the top of the mesa structure, and covers the top contact, to form the first dielectric layer. Next, an opening is formed in the first dielectric layer and exposing the bottom contact. The dielectric layer is formed by the initial dielectric layer and the other dielectric layer.

Referring to FIG. 45, step 7 includes forming a bottom-connected structure 07 in the opening;

Herein, the material of the bottom-connected structure 07 is deposited into the opening and on the bottom contact 06 by a conventional vapor deposition process.

Referring to FIG. 46, step 8 includes bonding the bottom-connected structure 07 with an IC backplane 00 by turning the semiconductor substrate 00′ upside down; then, removing the semiconductor substrate 00′.

Herein, the semiconductor substrate 00′ with the epitaxial structure is firstly turned upside down; then, the bottom-connected structure 07 is bonded with a pad of the IC backplane 00. After the bonding process, the semiconductor substrate 00 is removed by a conventional removing process, such as a laser lift-off method.

Referring to FIGS. 47 and 48, step 9 includes forming a top contact 09 and a top conductive layer 08 on the second epitaxial layer 02.

Herein, referring to FIG. 47, the top contact 09 is deposited on the top of the second-type epitaxial layer 02 with a mask protecting the other region, and then removing the mask. Finally, referring to FIG. 48, a top conductive layer 08 is deposited on the second epitaxial layer 02 by a conventional vapor deposition process.

It is understood by those skilled in the art that, the micro display panel is not limited by the structure mentioned above, and may include more or less components than those as illustrated, or some components may be combined, or a different component may be utilized.

It is understood by those skilled in the art that, all or part of the steps for implementing the foregoing embodiments may be implemented by hardware, or may be implemented by a program which instructs related hardware. The program may be stored in a flash memory, in a conventional computer device, in a central processing module, in an adjustment module, etc.

The above descriptions are merely embodiments of the present disclosure, and the present disclosure is not limited thereto. A modifications, equivalent substitutions and improvements made without departing from the conception and principle of the present disclosure shall fall within the protection scope of the present disclosure.

Further embodiments also include various subsets of the above embodiments including embodiments as shown in FIGS. 1-48 combined or otherwise re-arranged in various other embodiments.

Although the detailed description contains many specifics, these should not be construed as limiting the scope of the invention but merely as illustrating different examples and aspects of the invention. It should be appreciated that the scope of the invention includes other embodiments not discussed in detail above. For example, the approaches described above can be applied to the integration of functional devices other than LEDs and OLEDs with control circuitry other than pixel drivers. Examples of non-LED devices include vertical cavity surface emitting lasers (VCSEL), photodetectors, micro-electro-mechanical system (MEMS), silicon photonic devices, power electronic devices, and distributed feedback lasers (DFB). Examples of other control circuitry include current drivers, voltage drivers, trans-impedance amplifiers, and logic circuits.

The preceding description of the disclosed embodiments is provided to enable any person skilled in the art to make or use the embodiments described herein and variations thereof. Various modifications to these embodiments will be readily apparent to those skilled in the art, and the generic principles defined herein may be applied to other embodiments without departing from the spirit or scope of the subject matter disclosed herein. Thus, the present disclosure is not intended to be limited to the embodiments shown herein but is to be accorded the widest scope consistent with the following claims and the principles and novel features disclosed herein.

Features of the present invention can be implemented in, using, or with the assistance of a computer program product, such as a storage medium (media) or computer readable storage medium (media) having instructions stored thereon/in which can be used to program a processing system to perform any of the features presented herein. The storage medium can include, but is not limited to, high-speed random access memory, such as DRAM, SRAM, DDR RAM or other random access solid state memory devices, and may include non-volatile memory, such as one or more magnetic disk storage devices, optical disk storage devices, flash memory devices, or other non-volatile solid state storage devices. Memory optionally includes one or more storage devices remotely located from the CPU(s). Memory or alternatively the non-volatile memory device(s) within the memory, comprises a non-transitory computer readable storage medium.

Stored on any machine readable medium (media), features of the present invention can be incorporated in software and/or firmware for controlling the hardware of a processing system, and for enabling a processing system to interact with other mechanisms utilizing the results of the present invention. Such software or firmware may include, but is not limited to, application code, device drivers, operating systems, and execution environments/containers.

It will be understood that, although the terms “first,” “second,” etc. may be used herein to describe various elements or steps, these elements or steps should not be limited by these terms. These terms are only used to distinguish one element or step from another.

The terminology used herein is for the purpose of describing particular embodiments only and is not intended to be limiting of the claims. As used in the description of the embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if”' may be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” may be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art to best utilize the invention and the various embodiments.

1. A micro LED panel having a micro LED array, comprising a plurality of micro LED structures, wherein each of the plurality of micro LED structures comprises:
a mesa structure, comprising a first-type epitaxial layer, a light-emitting layer, and a second-type epitaxial layer from bottom to top; and
a re-growth layer, grown at least on a sidewall of the light-emitting layer.

2. The micro LED panel according to claim 1, wherein the re-growth layer is grown on a whole of the sidewall of the light-emitting layer and a part of the second-type epitaxial layer.

3. The micro LED panel according to claim 1, wherein the re-growth layer is not parallel to an extending direction of the light-emitting layer.

4. The micro LED panel according to claim 3, wherein an inclined angle of the re-growth layer relative to the extending direction of the light-emitting layer is about 30 degrees to about 90 degrees.

5. The micro LED panel according to claim 1, wherein a diameter of the mesa structure is less than or equal to about 3 μm.

6. The micro LED panel according to claim 1, wherein:
the light-emitting layer comprises a top surface, an edge surface, and a bottom surface;
the re-growth layer is grown on the edge surface of the light-emitting layer; and
the re-growth layer is not grown on the top surface and the bottom surface of the light-emitting layer.

7. The micro LED panel according to claim 6, wherein:
the light-emitting layer comprises a plurality of pairs of quantum wells; and
the re-growth layer is not parallel to a surface of each of the plurality of pairs of quantum wells.

8. The micro LED panel according to claim 6, wherein a cross section of the light-emitting layer has a straight line shape without any bending.

9. The micro LED panel according to claim 1, wherein:
a material of the re-growth layer with intrinsic doped ions is the same as a material of the first-type epitaxial layer or a material of the second-type epitaxial layer; and
the material of the re-growth layer does not include extrinsic doping ions.

10. The micro LED panel according to claim 1, wherein a material of the re-growth layer is one or more of GaP, AlP, GaAs, InP, AlInP, GaInP, AlN, GaN, and/or InN.

11. The micro LED panel according to claim 1, wherein:
a material of the re-growth layer is monocrystal;
a material of the first-type epitaxial layer is monocrystal; and
a material of the second-type epitaxial layer is monocrystal.

12. The micro LED panel according to claim 1, wherein a band gap of the re-growth layer is greater than a band gap of the light-emitting layer.

13. The micro LED panel according to claim 1, wherein a thickness of the re-growth layer is less than a thickness of the light-emitting layer.

14. The micro LED panel according to claim 13, wherein a thickness of the re-growth layer is less than or equal to about 100 nm.

15. The micro LED panel according to claim 1, wherein resistance of the re-growth layer is higher than resistance of the light-emitting layer.

16. The micro LED panel according to claim 15, wherein the re-growth layer is not electrically conductive.

17. The micro LED panel according to claim 1, wherein:
a dielectric layer is further formed between the mesa structure of adjacent micro LED structures of the plurality of micro LED structures; and
the dielectric layer is further formed on a surface of the re-growth layer.

18. The micro LED panel according to claim 17, wherein:
a bottom-connected structure is formed at a bottom of the mesa structure and electrically connected to the first-type epitaxial layer; and
a top conductive layer is formed on the second-type epitaxial layer and electrically connected to the second-type epitaxial layer.

19. The micro LED panel according to claim 17, wherein a material of the dielectric layer is one or more of SiO₂, SiNₓ, Al₂O₃, AlN, HfO₂, TiO₂, and/or ZrO₂.

20. The micro LED panel according to claim 1, wherein:
a material of the first-type epitaxial layer is one or more of p-type GaAs, InGaAs, GaP, GaN, InGaN, AlGaN, AlInP, GaInP, and/or AlGaInP; and
a material of the second-type epitaxial layer is one or more of n-type GaAs, InGaAs, GaP, GaN, InGaN, AlGaN, AlInP, GaInP, and/or AlGaInP.

21-91. (canceled)
